(19) United States
(12) Patent Application Publication
(10) Pub. No.: US 2026/0353671 A1
(43) Pub. Date: Nov. 5, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Hai-Dang TRINH, Hsinchu (TW); Chi-Hung LU, Hsinchu (TW); Shu-Han CHAO, Hsinchu (TW); Jhih-Bin CHEN, Hsinchu (TW); Yao-Wen CHANG, Taipei (TW); Cheng-Yuan TSAI, Chu-Pei City (TW); Chung-Yi YU, Hsin-Chu (TW)

(21) Appl. No.: 19/196,410

(22) Filed: May 1, 2025

(51) Int. Cl. H10B 63/10; H10D 30/00; H10D 30/43; H10D 62/10; H10N 70/00; H10N 70/20; H10W 20/40; H10W 20/41

(52) U.S. Cl. CPC H10B 63/10; H10N 70/063; H10N 70/231; H10N 70/826; H10W 20/435; H10W 20/498; H10D 30/43; H10D 30/502; H10D 62/121

(57) ABSTRACT

A phase change material (PCM) device may be manufactured for linear operation to achieve a high level of accuracy and reliability in the electrical resistance states of the PCM device for multi-bit operation. The PCM device may be manufactured to include a two-piece liner arrangement that includes a first liner between a PCM layer and a bottom contact structure of the PCM device, and a second liner on at least one sidewall of the PCM layer. The two-piece liner arrangement may be formed by depositing and patterning different layers. Thus, the first liner and the second liner are formed from the different layers. This enables attributes such as material, thickness, and/or electrical resistance of the first and second liners to be independently selected, which provides for increased flexibility in configuring various performance attributes of the PCM device such as power consumption and/or memory window.

### BACKGROUND

Phase change materials (PCMs) are often included in semiconductor devices to implement various functions such as switching, memory, and/or storage, among other examples. Switching and/or data retention may be implemented based on the structural phase in a PCM layer in a semiconductor device. For example, the structural phase of the PCM layer may be selectively switched between an amorphous phase and a crystalline phase to achieve switching and/or different data retention states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of a portion of an example semiconductor device described herein.

FIGS. 2A-2E illustrate example electrical resistance states of a phase change material (PCM) device described herein.

FIGS. 3A-3D are diagrams of example attributes of materials included in one or more liners of a PCM device described herein.

FIGS. 4A-4Q are diagrams of an example implementation of forming a semiconductor device described herein.

FIG. 5 is a diagram of a portion of an example semiconductor device described herein.

FIGS. 6A-6H are diagrams of an example implementation of forming a semiconductor device described herein.

FIG. 7 is a diagram of a portion of an example semiconductor device described herein.

FIGS. 8A and 8B are diagrams of an example implementation of forming a semiconductor device described herein.

FIG. 9 is a diagram of a portion of an example semiconductor device described herein.

FIGS. 10A and 10B are diagrams of an example implementation of forming a semiconductor device described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device may include a phase change material (PCM) based memory device such as a PCM memory device that includes a PCM layer. The electrical resistance of the PCM layer may be dependent on the structural phase of the PCM layer. For example, when a structural phase of the PCM layer is amorphous, the PCM layer may have a high electrical resistance. Conversely, when the structural phase of the PCM layer is crystalline, the PCM layer may have a low electrical resistance. The electrical resistance of the PCM layer may be measured or otherwise detected, and different levels of electrical resistance of the PCM layer may correspond to different logical values for data stored in the PCM memory device. For example, a low electrical resistance state may correspond to a 0 (zero) value, and a high electrical resistance state may correspond to a 1 (one) value.

In some cases, a PCM memory device may be manufactured to support more than two electrical resistance states, which provides for multi-bit operation. For example, a PCM memory device may be manufactured to support four electrical resistance states, which provides for two-bit operation. This enables the PCM memory to selectively store one of four logical values, such as a 00 value, a 01 value, a 10 value, or a 11 value. However, multi-bit operation reduces the difference in electrical resistance between the different electrical resistance states associated with the supported logical values, thus making the PCM memory device more prone to operational errors.

In some implementations described herein, a PCM device (e.g., a PCM memory device) may be manufactured for linear operation to achieve a high level of accuracy and reliability in the electrical resistance states of the PCM device for multi-bit operation. As described herein, a PCM device may be manufactured to include a two-piece liner arrangement that includes a first liner between a PCM layer and a bottom contact structure of the PCM device, and a second liner on at least one sidewall of the PCM layer. Electrons may flow from the bottom contact structure through at least the first liner before entering the PCM layer and flowing to a top electrode layer of the PCM structure. The distance traversed through the first liner (and in some cases, the second liner) by the electrons may be configured by generating a high resistance region in the PCM layer (e.g., through phase change switching). The first liner and the second liner may both have electrical resistances that are greater than the electrical resistance of the PCM layer, and that are less than the electrical resistance of the high resistance region. Thus, varying the distance traversed through the first liner and/or through the second liner (e.g., by controlling the size and/or the presence of the high resistance region) by the electrons varies the overall electrical resistance of the PCM device.

As further described herein, the two-piece liner arrangement may be formed by depositing and patterning different layers. Thus, the first liner and the second liner are formed from the different layers. This enables attributes such as material, thickness, and/or electrical resistance of the first and second liners to be independently selected, which provides for increased flexibility in configuring various performance attributes of the PCM device such as power consumption and/or memory window (e.g., the differences in electrical resistance between different electrical resistance states of the PCM device), among other examples.

Additionally and/or alternatively, the first and second liners may be formed of one or more materials that have a significantly higher resistivity (ρ) than the PCM material of the PCM layer to further increase the memory window of the PCM device. The higher resistivity of the material(s) of the first and second liners results in the first and second liners having a greater contribution to the overall electrical resistance of the PCM device than if the first and second liners were formed of a lower resistivity material such as tantalum nitride (TaN). In this way, smaller differences in the distances traveled by electrons through the first liner and/or through the second liner result in greater differences in the overall electrical resistance of the PCM device than if a lower resistivity material were used for the liners, enabling the electrical resistance states of the PCM device to be further apart. This may increase the reliability of the PCM device, may reduce the rate of memory errors exhibited by the PCM device during operation of the PCM device, and/or may make the PCM device more tolerant to manufacturing variances.

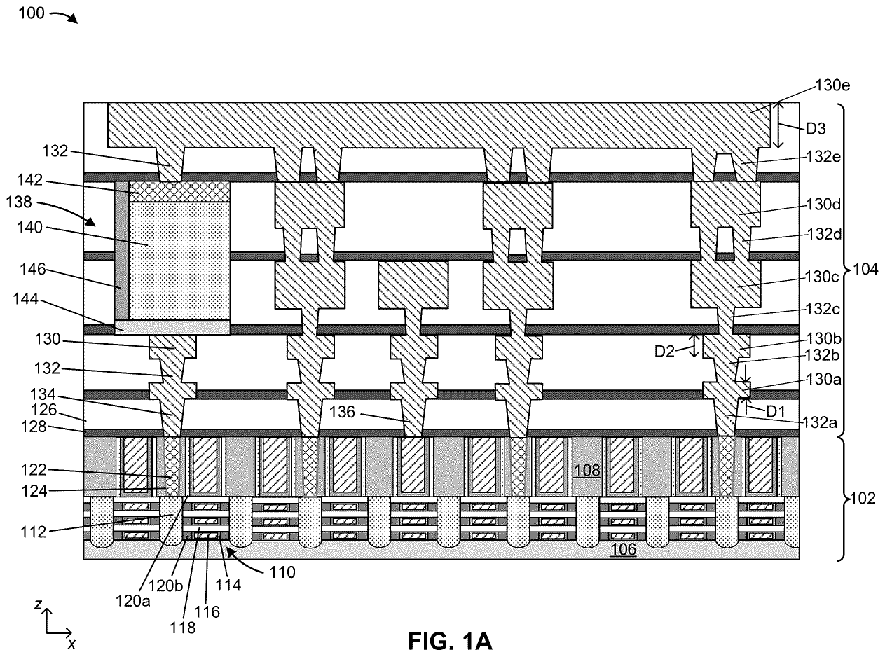

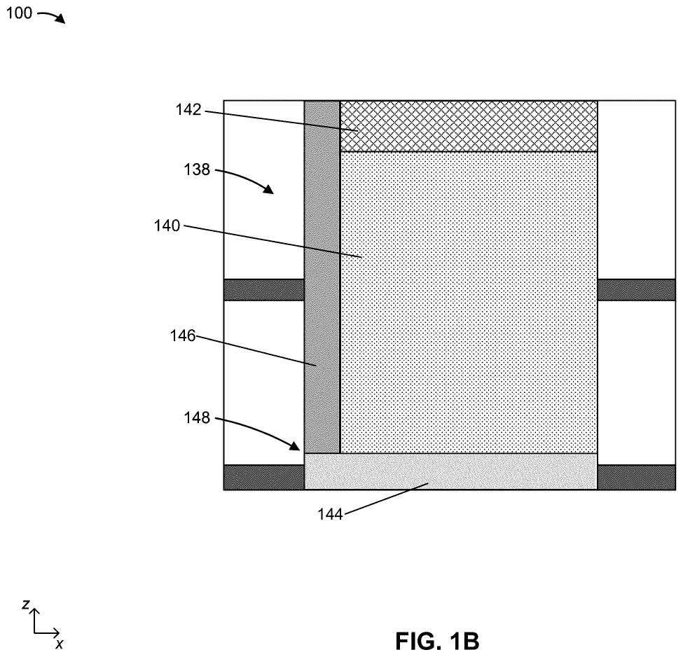

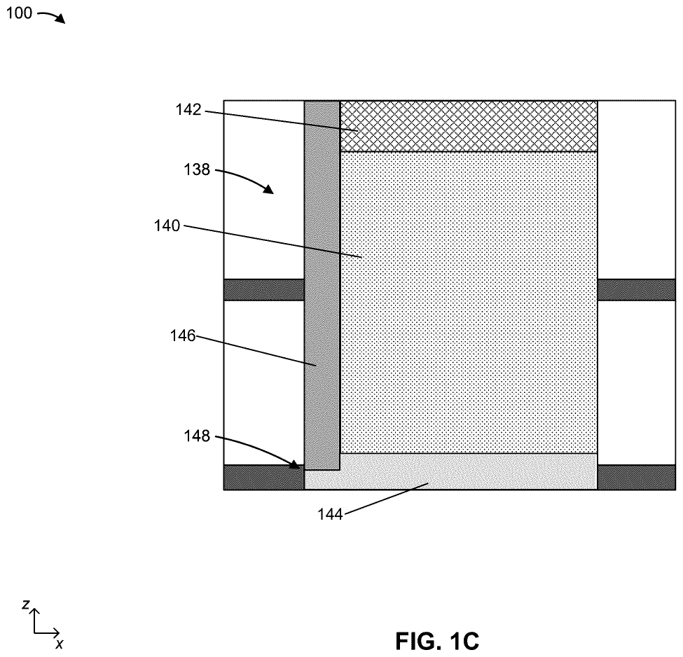

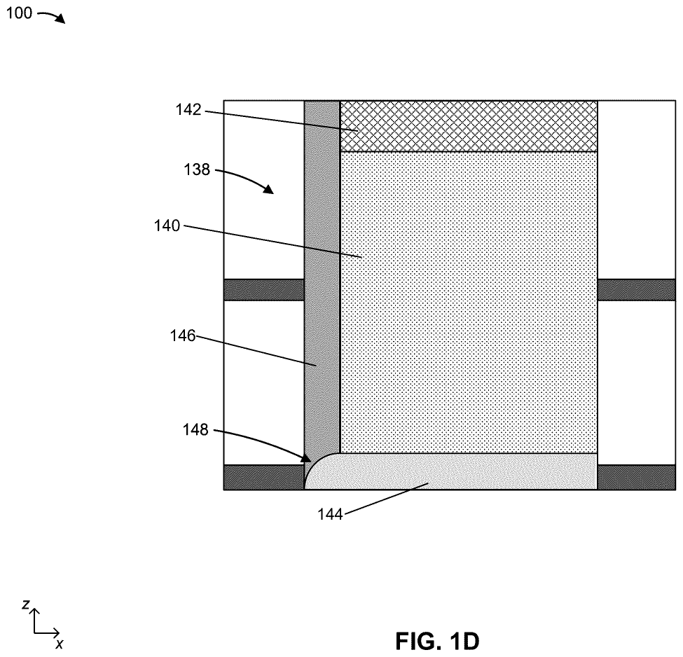

FIGS. 1A-1D are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe)) layers.

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal). In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114. In some implementations, the sidewall spacers 120a are in contact with the work function metal layer. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 122b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The source/drain regions 112 are electrically coupled and/or physically coupled with source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the device layer 102 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 may further include a plurality of layers of conductive structures in the dielectric layers (e.g., the ILD layers 126 and the ESLs 128) of the interconnect layer 104. The conductive structures in the interconnect layer 104 may be interconnected to enable signals and/or power to be distributed throughout the semiconductor device 100 through the interconnect layer 104. The conductive structures include a combination of metallization structures 130 and interconnect structures 132. The metallization structures 130 may include trenches, conductive traces, and/or other types of conductive structures that primarily extend in the x-direction and/or in the y-direction in the interconnect layer 104. The interconnect structures 132 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 130 and an interconnect structure 132.

The metallization structures 130 and the interconnect structures 132 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 130 and/or the interconnect structures 132 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 130 and the interconnect structures 132 of the interconnect layer 104 may be arranged in a vertical manner (e.g., in the z-direction). In other words, a plurality of stacked metallization structures 130 and interconnect structures 132 may extend between the device layer 102 and a top of the interconnect layer 104 to facilitate electrical signals and/or power to be routed between the device layer 102 and connection structures (not shown) of the semiconductor device 100.

The plurality of stacked metallization structures 130 may be arranged in layers that may be referred to as M-layers, and the plurality of stacked interconnect structures 132 may be arranged in layers that may be referred to as V-layers. A bottom-most layer of interconnect structures 132a in the interconnect layer 104 may be referred to as a V0 layer, and may include source/drain interconnect structures 134 that are electrically coupled and/or physically coupled to the source/drain contact structures 122 of one or more integrated circuit devices 110, and gate interconnect structures 136 that are electrically coupled and/or physically coupled to the gate structures 116 of one or more integrated circuit devices 110. The source/drain interconnect structures 134 are referred to source/drain vias (VDs), and the gate interconnect structures 136 are referred to as gate vias (VGs). In some implementations, gate contacts (not shown) are included between the gate structures 116 and the gate interconnect structures 136.

A layer of metallization structures 130a may be referred to as a metal-0 (M0) layer, and may be located above the layer of interconnect structures 132a (including the source/drain interconnect structures 134 and the gate interconnect structures 136) in the interconnect layer 104. The metallization structures 130a in the M0 layer may be electrically coupled and/or physically coupled with the source/drain interconnect structures 134 and/or the gate interconnect structures 136.

Additional layers of conductive structures may be arranged in a similar manner in the interconnect layer 104. For example, a layer of interconnect structures 132b may be referred to as a via-1 (V1) layer that is located above and electrically coupled and/or physically coupled to the layer of metallization structures 130a in the M0 layer. A layer of metallization structures 130b may be referred to as a metal-1 (M1) layer that is located above and electrically coupled and/or physically coupled to the layer of interconnect structures 132b in the V1 layer. A layer of interconnect structures 132c may be referred to as a via-1 (V2) layer that is located above and electrically coupled and/or physically coupled to the layer of metallization structures 130b in the M1 layer. A layer of metallization structures 130c may be referred to as a metal-2 (M2) layer that is located above and electrically coupled and/or physically coupled to the layer of interconnect structures 132c in the V2 layer. A layer of interconnect structures 132d may be referred to as a via-3 (V3) layer that is located above and electrically coupled and/or physically coupled to the layer of metallization structures 130c in the M2 layer. A layer of metallization structures 130d may be referred to as a metal-3 (M3) layer that is located above and electrically coupled and/or physically coupled to the layer of interconnect structures 132d in the V3 layer. A layer of interconnect structures 132e may be referred to as a via-4 (V4) layer that is located above and electrically coupled and/or physically coupled to the layer of metallization structures 130d in the M3 layer. A layer of metallization structures 130e may be referred to as a metal-4 (M4) layer that is located above and electrically coupled and/or physically coupled to the layer of interconnect structures 132e in the V4 layer. In some implementations, the interconnect layer 104 includes a different quantity of layers of metallization structures 130 and/or a different quantity of layers of interconnect structures 132 than the quantities shown in FIG. 1A.

As further shown in FIG. 1A, the sizes metallization structures 130 of the layers of metallization structures 130 may be greater the further up in the interconnect layer 104 the layers of metallization structures 130 are located. For example, the thickness of the metallization structures 130a (e.g., in the M0 layer) may have a first thickness (indicated in FIG. 1A as a dimension D1), the thickness of the metallization structures 130b (e.g., in the M1 layer) may have a second thickness (indicated in FIG. 1A as a dimension D2), and the second thickness may be greater than the first thickness. As another example, the thickness of the metallization structures 130a (e.g., in the M0 layer) may have a first thickness (indicated in FIG. 1A as a dimension D1), the thickness of the metallization structures 130e (e.g., in the M4 layer) may have a second thickness (indicated in FIG. 1A as a dimension D3), and the second thickness may be greater than the first thickness. As another example, the thickness of the metallization structures 130b (e.g., in the M1 layer) may have a first thickness (indicated in FIG. 1A as a dimension D2), the thickness of the metallization structures 130e (e.g., in the M4 layer) may have a second thickness (indicated in FIG. 1A as a dimension D3), and the second thickness may be greater than the first thickness.

The increasing thickness of the layers of metallization structures 130 in the interconnect layer 104 enables higher voltage and/or higher current signals and/or power to be distributed closer to the top of the interconnect layer 104. As signals propagate further down in the interconnect layer 104, voltage and/or power of the signals is reduced to achieve power efficiency and/or to enable a higher density of metallization structures 130 to be arranged at the bottom of the interconnect layer 104.

As further shown in FIG. 1A, the semiconductor device 100 may include one or more PCM devices 138 in the interconnect layer 104. A PCM device 138 may include a PCM switch, a PCM memory device, and/or another type of structure that includes a PCM layer 140. The PCM device 138 may be included in and/or may extend through one or more of the dielectric layers (e.g., one or more of the ILD layers 126, one or more of the ESLs 128) of the interconnect layer 104.

The PCM device 138 may include an electrode layer 142 (e.g., a top electrode layer) over and/or on the PCM layer 140. The PCM device 138 may include a first liner 144 under a bottom surface of the PCM layer 140. The PCM device 138 may include a second liner 146 that is on at least one sidewall of the PCM layer 140, and that is electrically coupled and/or physically coupled to the first liner 144. The PCM device 138 may be electrically coupled and/or physically coupled to one or more conductive structures in the interconnect layer 104, such as a metallization structure 130b (e.g., in the M1 layer) or a metallization structure 130e (e.g., in the M4 layer). However, other connection arrangements are within the scope of the present disclosure.

The PCM layer 140 includes one or more materials that are capable of transitioning between two or more material phases or crystal structural phases. In particular, the PCM layer 140 includes one or more materials that are capable of transitioning between a crystalline structural phase (or crystalline material structure) and an amorphous structural phase (or non-crystalline material structure). For example, the PCM layer 140 may include a binary chalcogenide material such as germanium tellurium (GeTe), where a composition range of the PCM layer 140 (e.g., molar percentages of the germanium (Ge) and tellurium (Te)) corresponds to Ge₁₀₀₋ₓTeₓ. As another example, the PCM layer 140 may include a ternary chalcogenide material such as germanium antimony tellurium (GeSbTe).

In some implementations, a molar percentage of the tellurium in the PCM layer 140 is greater than a molar percentage of germanium. For example, the molar percentage of tellurium may be greater than or equal to approximately 51%. Additionally, or alternatively and in some implementations, a molar percentage of germanium in the PCM layer 140 is included in a range of approximately 43% to approximately 47%. However, other values and ranges for the molar percentage of germanium are within the scope of the present disclosure. In some implementations, a sheet resistance of the PCM layer 140 is included in a range of approximately 18 ohms per square (Ω/sq) to approximately 22 Ω/sq. However, other values and ranges for the sheet resistance are within the scope of the present disclosure.

The electrode layer 142 may be elongated in the x-direction and/or in the y-direction in the semiconductor device 100, and may include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. The electrode layer 142 may be located vertically between the PCM layer 140 of the PCM device 138 and the metallization structure 130e above the PCM device 138. The electrode layer 142 may be physically coupled and/or electrically coupled to the metallization structure 130e.

The first liner 144 and the second liner 146 may each be thin film layers of electrically conductive material having a high resistivity (e.g., greater than the resistivity of the PCM of the PCM layer 140 when the PCM is in a crystalline structural phase). The first liner 144 may be oriented in an approximately horizontal direction such that the first liner 144 extends primarily in the x-direction and/or in the y-direction, and may be located vertically between the metallization structure 130b and the PCM layer 140. Thus, the first liner 144 may be electrically coupled and/or physically coupled to the metallization structure 130b, and may electrically couple the PCM layer 140 and the second liner 146 to the metallization structure 130b.

The second liner 146 may be oriented in an approximately vertical direction such that the second liner 146 extends primarily in the z-direction. Thus the first liner 144 and the second liner 146 may be approximately perpendicular to each other and may form an approximate L-shape in the cross-section view of the PCM device 138. The second liner 146 may also extend in the y-direction alongside the PCM layer 140.

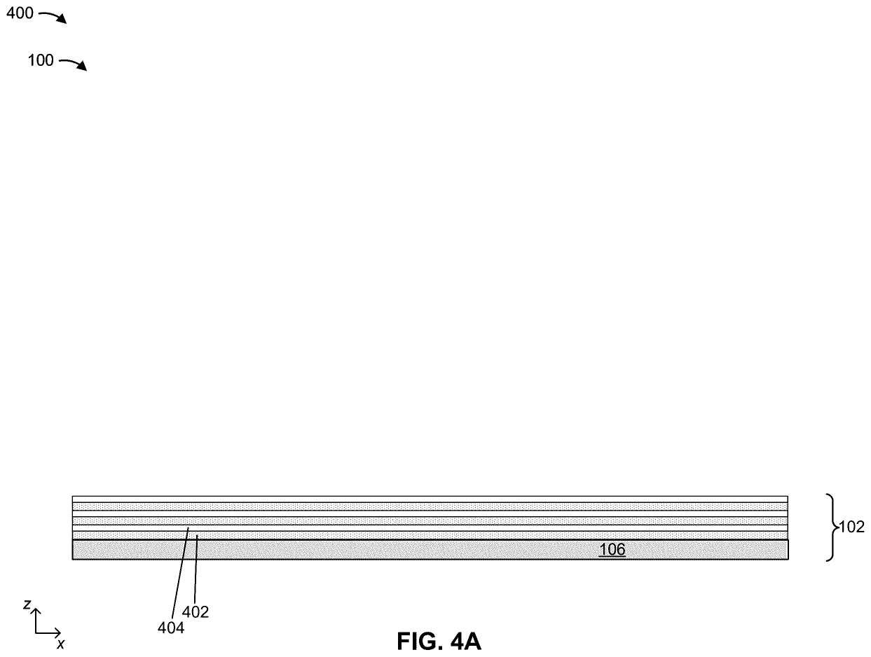

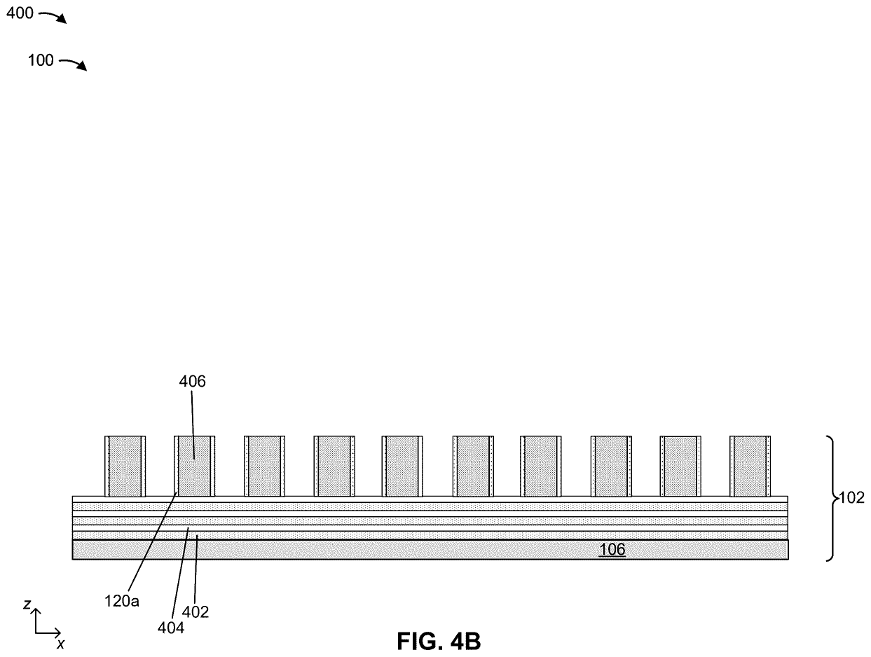

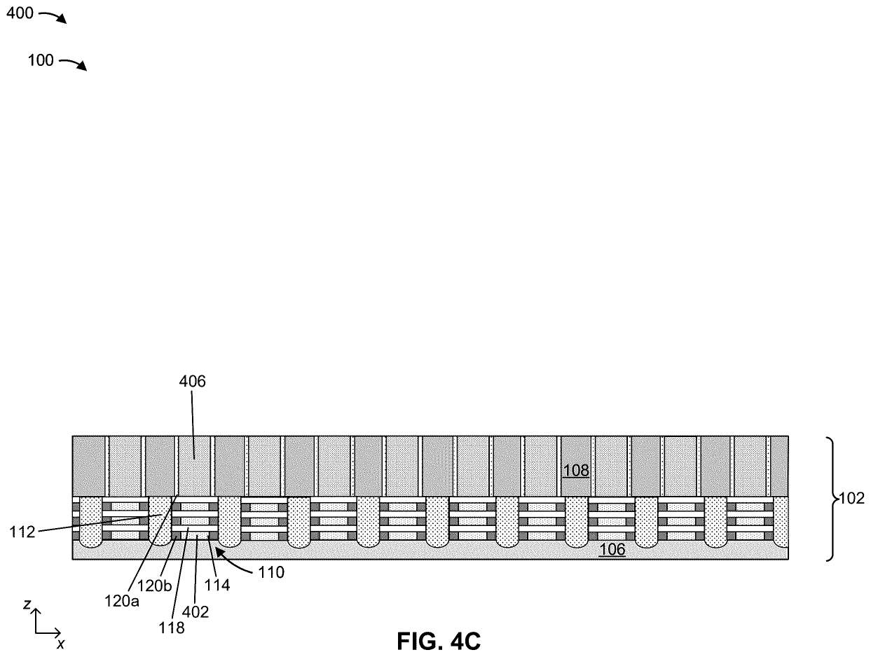

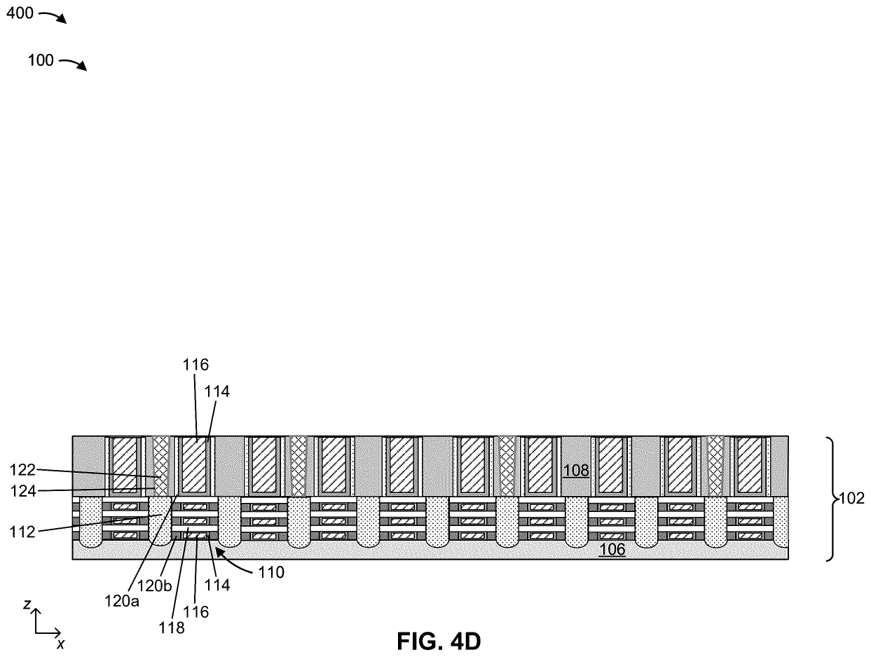

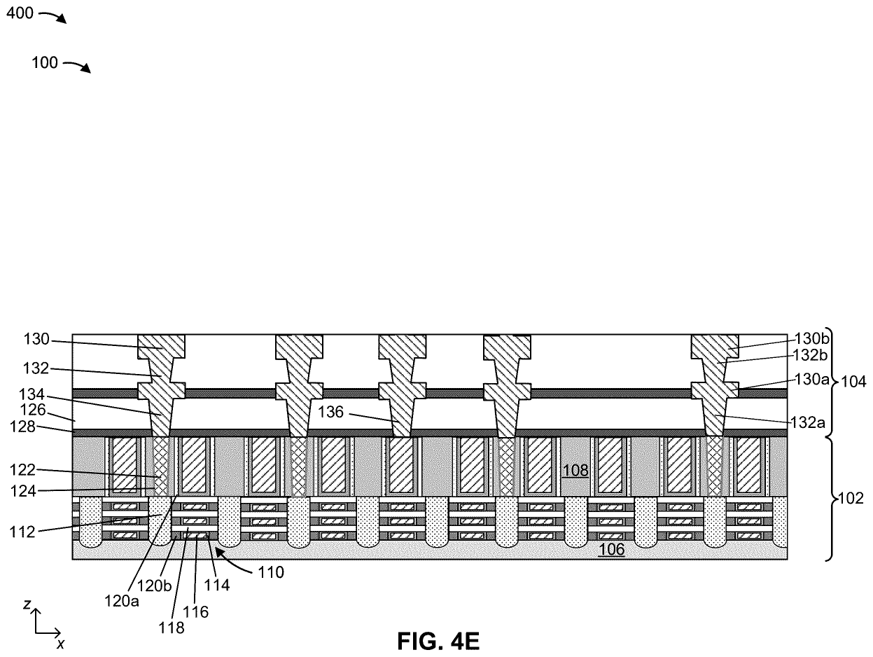

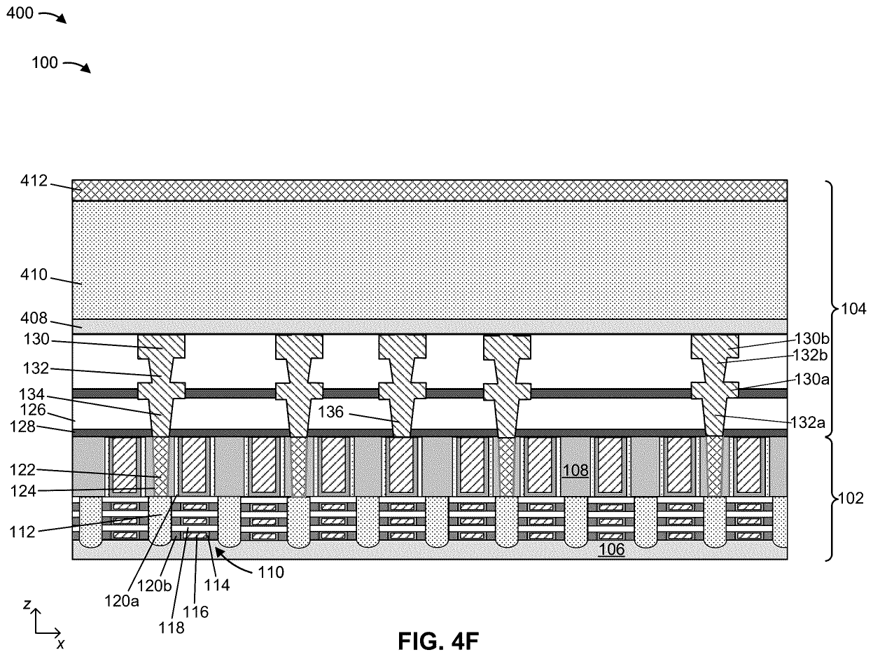

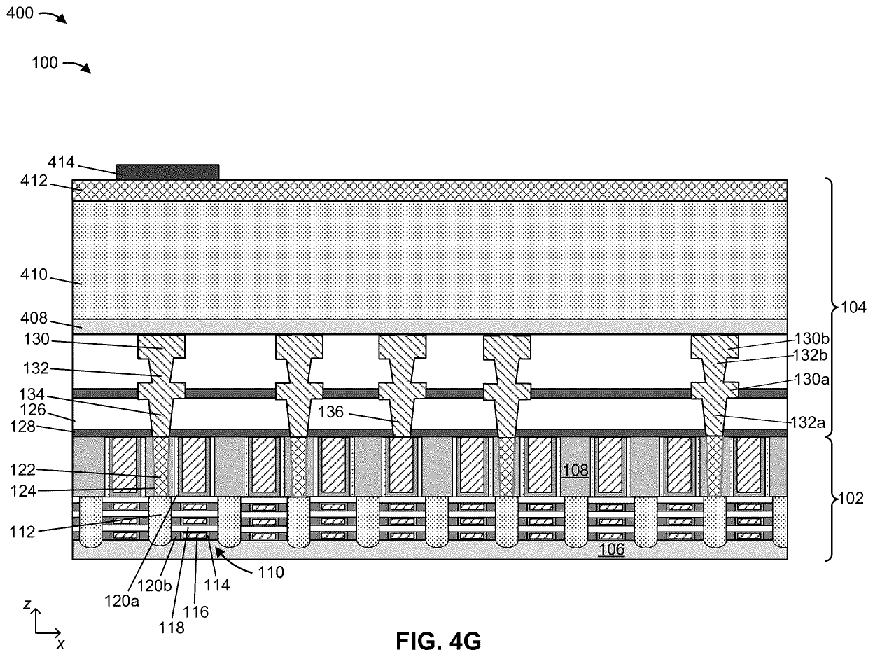

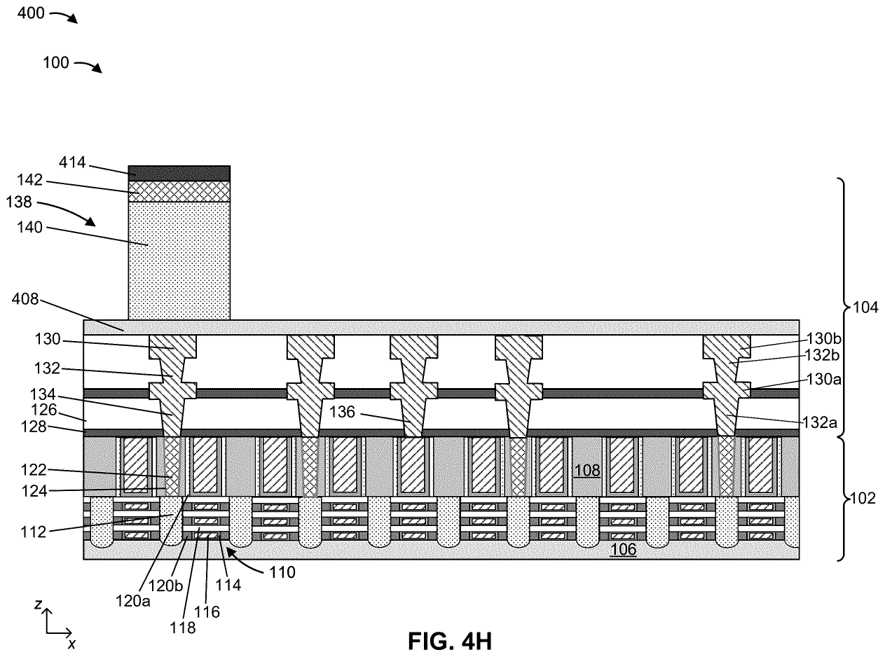

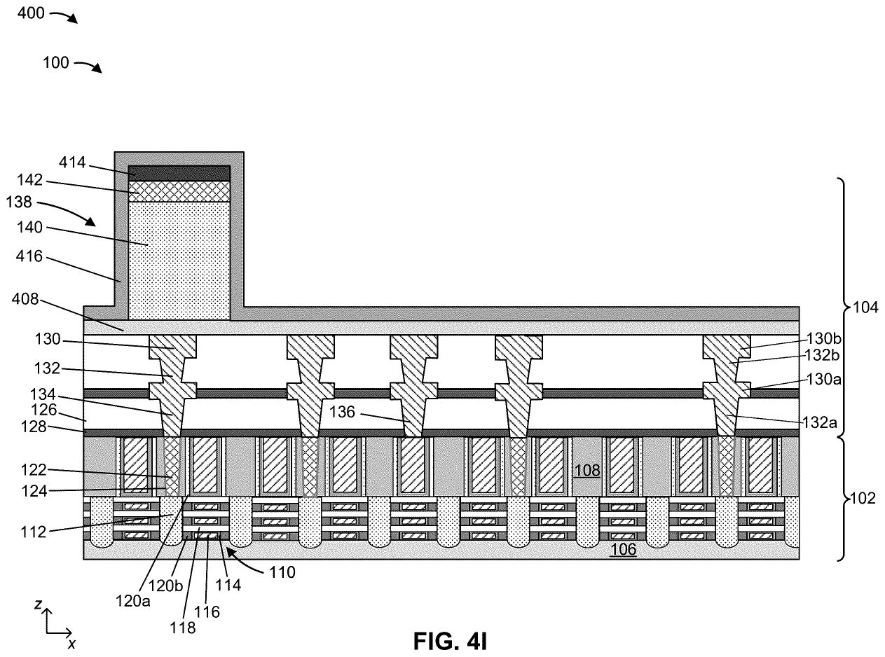

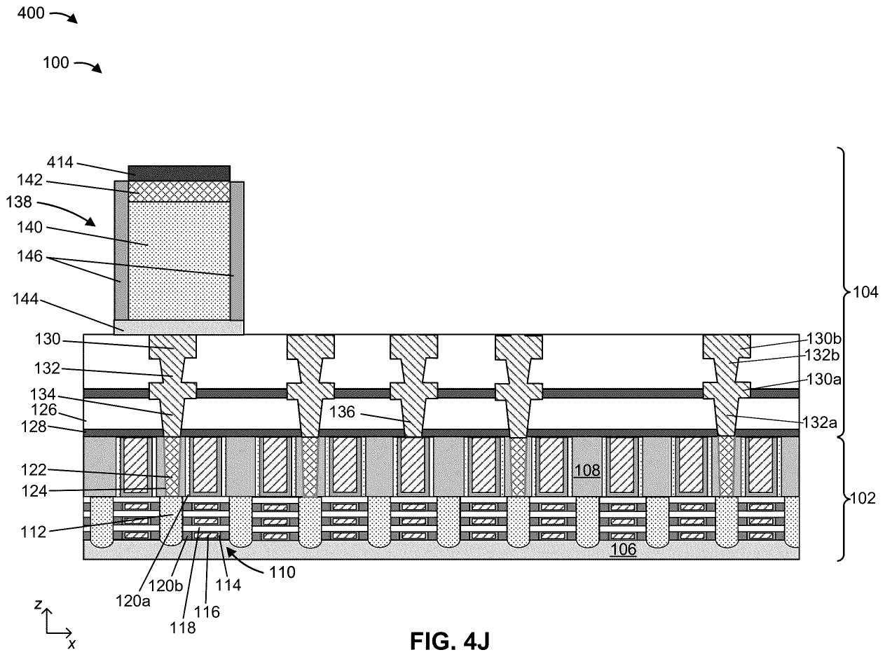

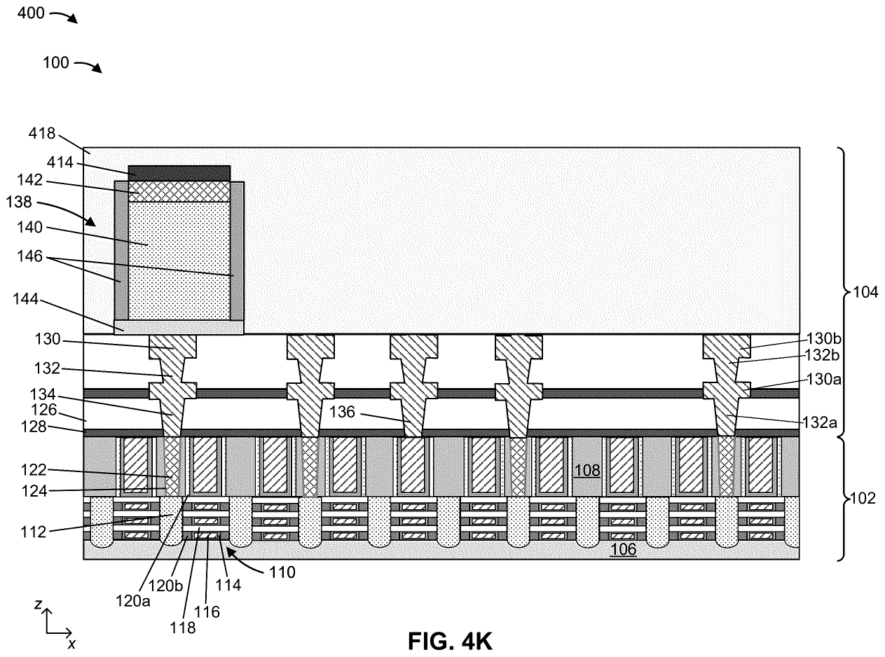

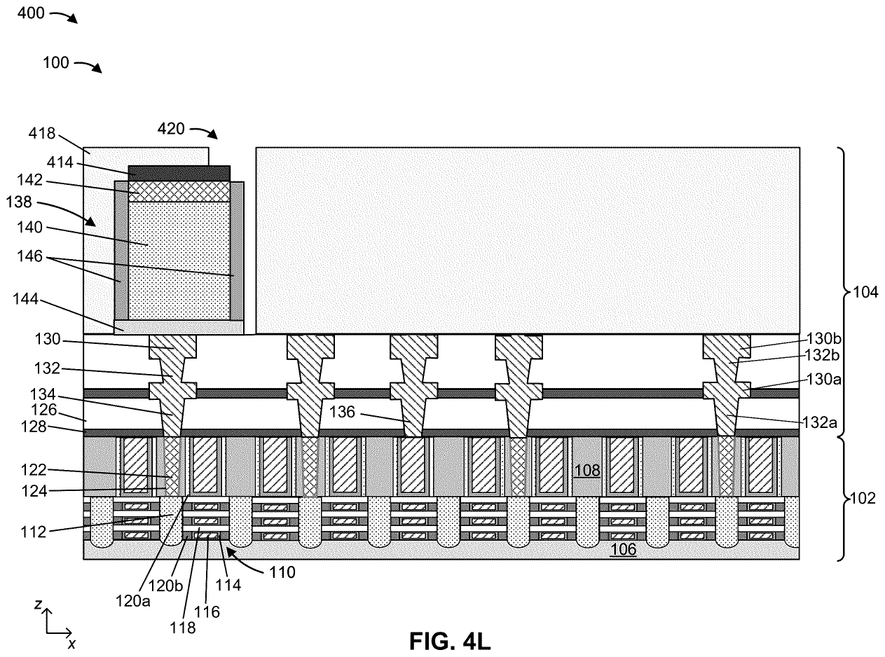

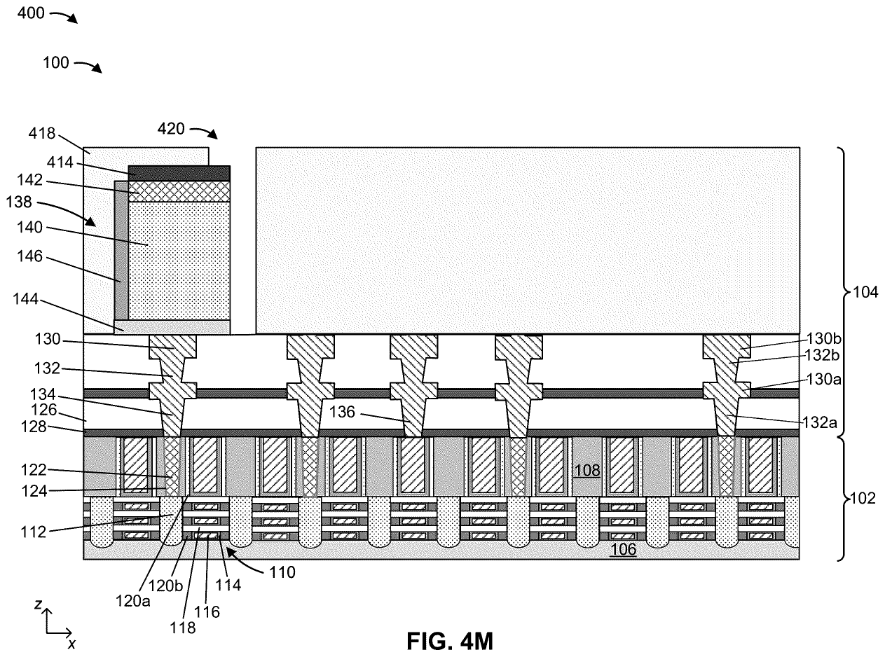

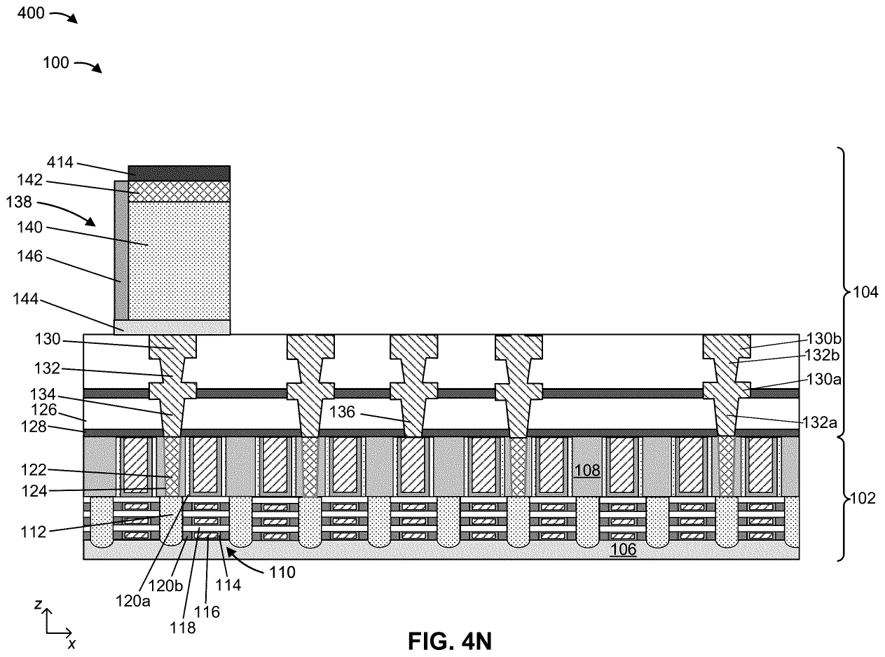

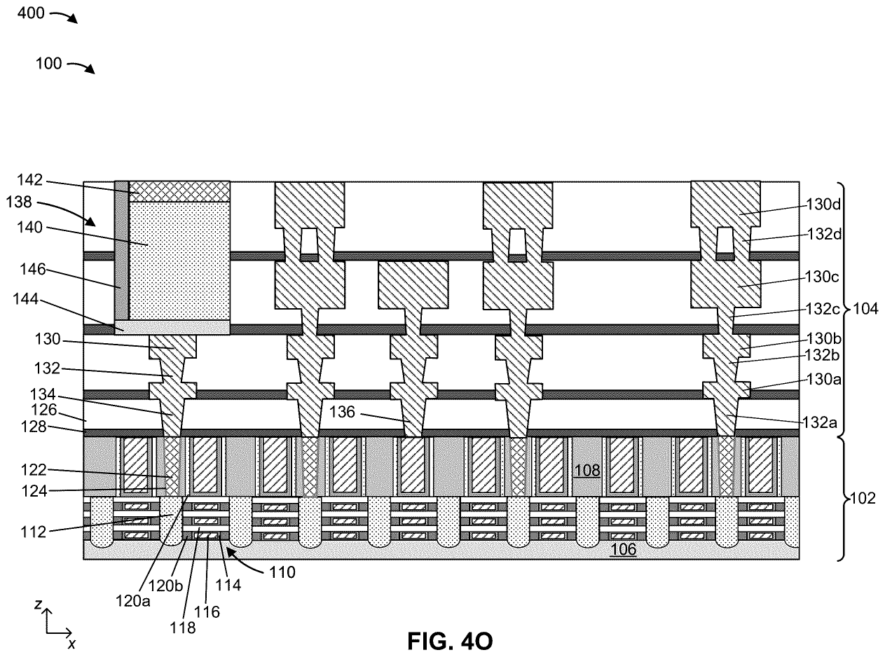

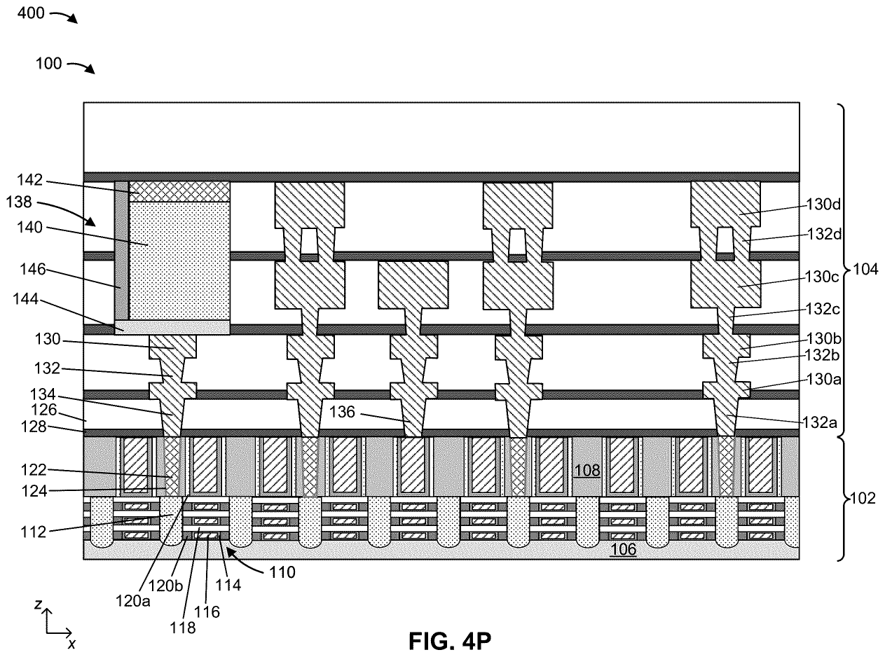

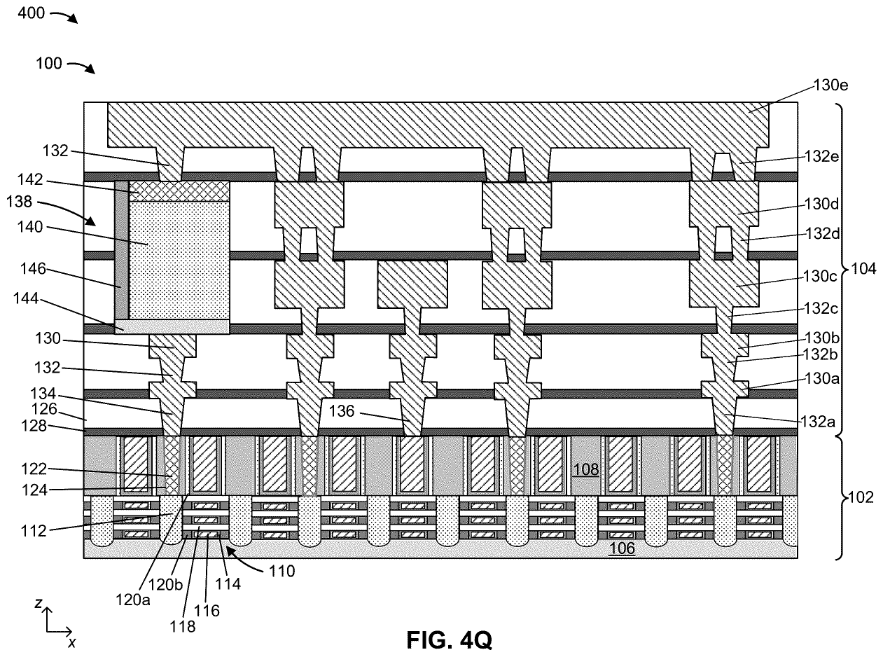

As described in connection with FIGS. 4A-4Q, the first liner 144 and the second liner 146 may be formed from different layers. This enables the first liner 144 and the second liner 146 to be formed of different materials, to be formed to have different thicknesses, and/or to be formed to have other different attributes. Thus, the thickness of the first liner 144 (e.g., in the z-direction) may be greater than the thickness of the second liner 146 (e.g., in the x-direction), or may be less than the thickness of the second liner 146. Alternatively, the thickness of the first liner 144 and the thickness of the second liner 146 may be approximately a same thickness.

Because the first liner 144 and the second liner 146 were formed from different layers, an interface between ends of the first liner 144 and the second liner 146 facing each other may be visible in an electron microscope image (e.g., a transmissive electron microscope (TEM) image) of the PCM device 138. As shown in FIG. 1A, the first liner 144 and the second liner 146 may be formed such that an end of the second liner 146 (e.g., a bottom or a bottom end) is over and/or on an end (e.g., a lateral end) of the first liner 144.

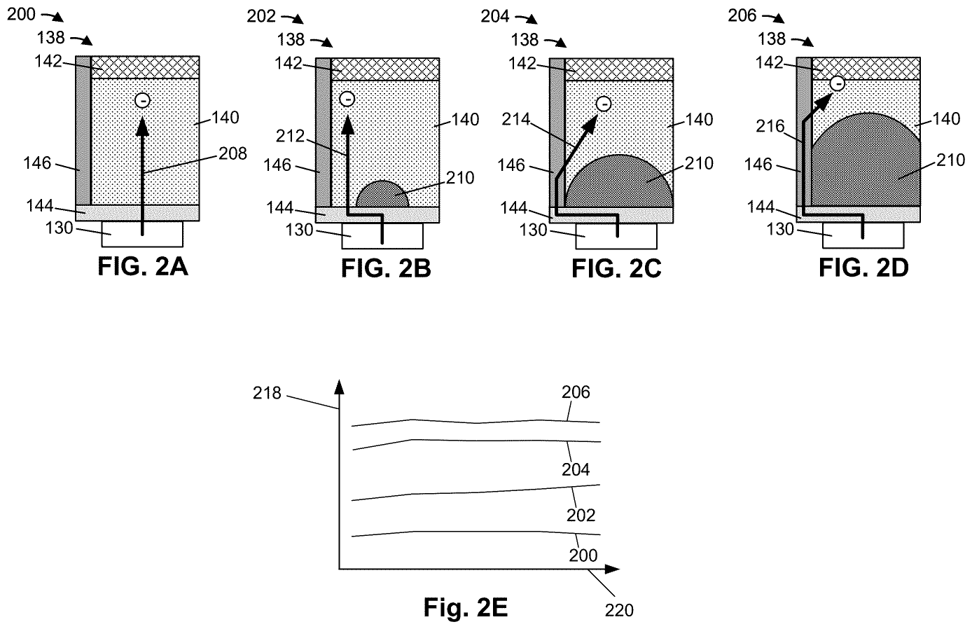

As described above, the first liner 144 and the second liner 146 may each include a material having a resistivity that is greater than the resistivity of the PCM of the PCM layer 140 when the PCM is in a crystalline structural phase. The first liner 144 and the second liner 146 may each include a material having a high resistivity, such as a resistivity greater than the resistivity of tantalum nitride (TaN). Alternatively, one of the first liner 144 or the second liner 146 may include tantalum nitride, while the other of the first liner 144 or the second liner 146 may include a material having a resistivity greater than the resistivity of tantalum nitride. As described in connection with FIGS. 2A-2E, the high resistivities of the material(s) of the first liner 144 and of the second liner 146 provide for a greater memory window for the PCM device 138, which reduces the likelihood of and/or the rate of memory errors during operation of the PCM device 138, and/or makes the PCM device 138 more tolerant to manufacturing process variations.

In some implementations, the first liner and the second liner 146 include the same material, such as a carbon-containing material, a nitride-containing material, and/or another electrically conductive material having a high resistivity. Examples of such materials include carbon-doped tantalum nitride (TaN:C), nitrogen-doped carbon (C:N), silicon-doped carbon (C:Si), amorphous carbon, diamond-like carbon (DLC), and/or aluminum nitride (AlN), among other examples.

A “high resistivity” may be defined as the resistivities of the materials of the first liner 144 and the second liner 146 each being at least approximately 100 times greater than the resistivity of the PCM of the PCM layer 140 (e.g., with the PCM is in a crystalline structural phase) to achieve a large memory window for the PCM device 138. However, other values are within the scope of the present disclosure.

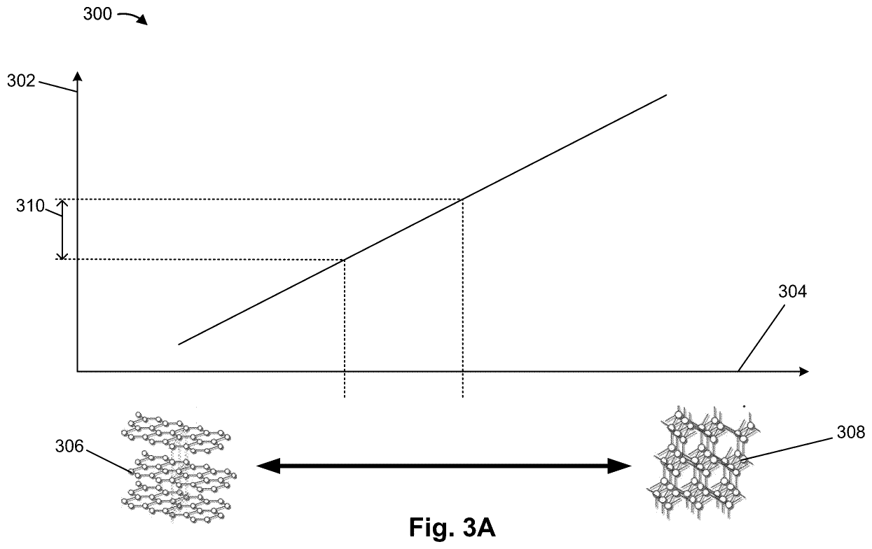

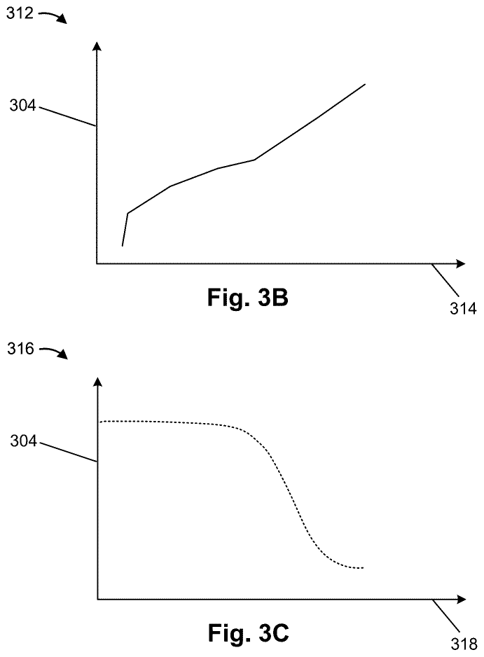

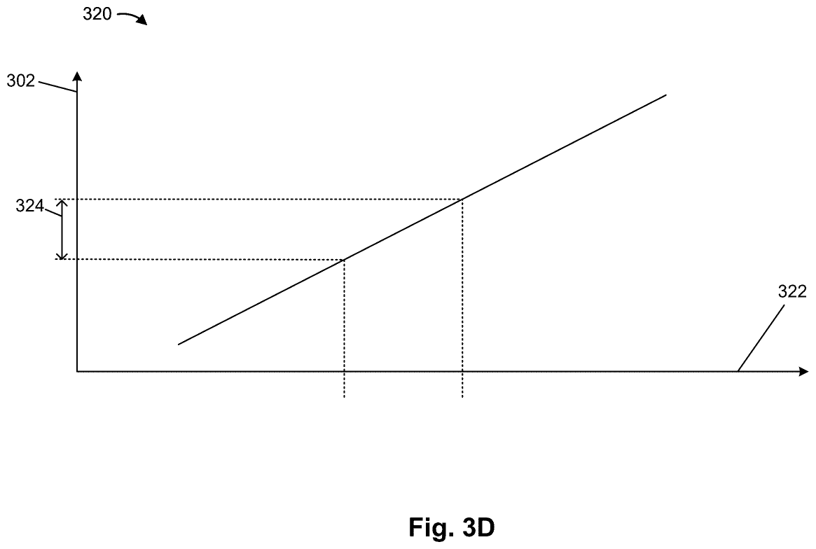

In some implementations, the resistivities of the materials of the first liner 144 and the second liner 146 are each included in a range of approximately 0.01 ohm-meters to approximately 0.1 ohm-meters to achieve a large memory window for the PCM device 138. As described in greater detail in connection with FIG. 3A, the composition of the crystal structure of the material of the first liner 144 and/or of the second liner 146 may contain a combination of carbon structures to achieve a resistivity in this range, such as a combination of two-dimensional graphene structures and three-dimensional diamond structures. Additionally and/or alternatively, and as described in greater detail in connection with FIG. 3A, the nitrogen (N) concentration in the material of the first liner 144 and/or of the second liner 146 may be selected to achieve a resistivity in this range. However, other values are within the scope of the present disclosure.

In some implementations, the first liner 144 and the second liner 146 are formed of the same material and, therefore, have approximately the same resistivity. In some implementations, the first liner 144 and the second liner 146 are formed of different materials. For example, the first liner 144 may be formed of carbon (C) and the second liner 146 may be formed of nitrogen-doped carbon (C:N). As another example, the first liner 144 may be formed of carbon (C), and the second liner 146 may be formed of aluminum nitride (AlN). As another example, the first liner 144 may be formed of carbon (C), and the second liner 146 may be formed of carbon-doped tantalum nitride (TaN:C). Other combinations of materials for the first liner 144 and the second liner 146 are within the scope of the present disclosure.

In implementations in which the first liner 144 and the second liner 146 contain different materials, the materials of the first liner 144 and the second liner 146 may have different resistivities. For example, the resistivity of the material of the first liner 144 may be less than the resistivity of the material of the second liner 146. Because the first liner 144 is electrically coupled to the metallization structure 130b, electrons propagate through the first liner 144 during operation of the PCM device 138, but do not necessarily propagate through the second liner 146, depending upon the electrical resistance state of the PCM device 138 (as explained in greater detail in connection with FIGS. 2A-2E). Thus, the first liner 144 will typically have a greater influence on the overall electrical resistance of the PCM device 138 than the second liner 146. The resistivity of the material of the first liner 144 being less than the resistivity of the material of the second liner 146 enables the PCM device 138 to operate more efficiently while providing for a greater memory window. This is because, when the PCM device 138 is configured in a high electrical resistance state such that electrons propagate through the second liner 146, the greater resistivity of the second liner 146 results in the PCM device 138 having a much higher overall electrical resistance in the high electrical resistance state than in a low electrical resistance state in which electrons do not propagate through the second liner 146 and instead propagate only through the first liner 144. However, other combinations of resistivities for the first liner 144 and the second liner 146 are within the scope of the present disclosure.

FIGS. 1B-1D illustrate examples of an interface 148 between the first liner 144 and the second liner 146 of the PCM device 138 in the semiconductor device 100. As shown in FIG. 1B, the interface 148 may be substantially flat and horizontal. Thus, the interface 148 may extend primarily in the x-direction and in the y-direction. A portion of a sidewall of the second liner 146 is in contact with an end surface of the first liner 144.

As shown in FIG. 1C, the bottom end of the second liner 146 may be recessed below the top surface of the first liner 144 such that the interface 148 is below the top surface of the first liner 144. This may occur in implementations in which some etching of the first liner 144 occurs when layers are etched to define the PCM layer 140 and/or the electrode layer 142. For example, and as illustrated and described in greater detail in connection with FIGS. 4H-4J, layers may be etched based on a patterned masking layer to define the PCM layer 140 and the electrode layer 142, whereas the layers from which the first liner 144 and the second liner 146 are formed are subsequently etched. Because the layer from which the first liner 144 was formed was deposited prior to etching of the layers from which the PCM layer 140 and the electrode layer 142 were formed, some etching of the layer from which the first liner 144 was formed may occur during etching of the layers from which the PCM layer 140 and the electrode layer 142 were formed, resulting in formation of recesses in ends of the first liner 144 that extend laterally outward from the PCM layer 140.

As shown in FIG. 1D, the interface 148 between the ends of the first liner 144 and the second liner 146 may be non-horizontal and/or may have some curvature or slope. This may occur due to etch loading during etching of the layers from which the PCM layer 140 and the electrode layer 142 were formed. In particular, etching of the layer from which the first liner 144 was formed may be greater further away from the PCM layer 140 than near the edge of the PCM layer 140 (e.g., because the etchant may more freely flow further away from the PCM layer 140 than near the edge of the PCM layer 140), resulting in the curved or sloped profile shown in FIG. 1D. However, other non-horizontal profiles for the interface 148 are within the scope of the present disclosure.

As indicated above, FIGS. 1A-1D are provided as examples. Other examples may differ from what is described with regard to FIGS. 1A-1D.

FIGS. 2A-2E illustrate example electrical resistance states of a PCM device 138 described herein. Each electrical resistance state may correspond to a logical value. For example, an example electrical resistance state 200 illustrated in FIG. 2A may correspond to a 00 logical value, an example electrical resistance state 202 illustrated in FIG. 2B may correspond to a 01 logical value, an example electrical resistance state 204 illustrated in FIG. 2C may correspond to a 10 logical value, and an example electrical resistance state 206 illustrated in FIG. 2D may correspond to a 11 logical value. However, other combinations of electrical resistance states and associated logical values are within the scope of the present disclosure. Additionally and/or alternatively, a PCM device 138 may be configured to support a different quantity of electrical resistance states than shown in FIGS. 2A-2D.

As shown in FIG. 2A, in the example electrical resistance state 200, the PCM layer 140 of the PCM device 138 is in a crystalline state. In other words, no amorphous high resistance region has been formed or programmed into the PCM layer 140 of the PCM device 138 in the electrical resistance state 200. In the electrical resistance state 200, charge carriers (e.g., electrons) may propagate from the metallization structure 130 coupled to the first liner 144 of the PCM device 138, through the first liner 144 and directly into the PCM layer 140 toward the electrode layer 142 above the PCM layer 140. Thus, the electrical resistance state 200 may be referred to as a low resistance state because of a direct propagation path 208 of the charge carriers.

As shown in FIG. 2B, in the electrical resistance state 202, a high resistance region 210 is located in the PCM layer 140. The high resistance region 210 may include a region of the PCM layer 140 having an amorphous or disordered structural phase. Because of the amorphous structural phase of the high resistance region 210, the electrical resistance in the high resistance region 210 is greater than the electrical resistance in a crystalline region of the PCM layer 140. The crystalline region of the PCM layer 140 has a crystalline structural phase and, therefore, a lower electrical resistance. Thus, a propagation path 212 for charge carriers in the electrical resistance state 202 is directed around the high resistance region 210 so that the charge carriers propagate through the lower electrical resistance region (e.g., the crystalline region) of the PCM layer 140 instead of the higher resistance region (e.g., the high resistance region 210) of the PCM layer 140. Moreover, the charge carriers propagate along the propagation path 212 for a greater distance through the first liner 144, which also has a greater electrical resistance than the crystalline region of the PCM layer 140. Thus, the PCM device 138 has a greater overall electrical resistance in the electrical resistance state 202 than in the electrical resistance state 200. The electrical resistance state 202 may be referred to as a medium low electrical resistance state.

As shown in FIG. 2C, in the electrical resistance state 204, a high resistance region 210 is located in the PCM layer 140 similar to the electrical resistance state 202. However, in the electrical resistance state 204, the high resistance region 210 is larger (e.g., occupies a greater area or volume of the PCM layer 140) than the high resistance region 210 in the electrical resistance state 202. Thus, in the electrical resistance state 204, the charge carriers propagate along a propagation path 214 for a greater distance through the first liner 144 than along the propagation path 212 in the electrical resistance state 202. Moreover, the greater size of the high resistance region 210 in the electrical resistance state 204 results in the charge carriers propagating along the propagation path 214 through a portion of the second liner 146. The greater propagation distance of the charge carriers through the first liner 144 and through the second liner 146 results in the PCM device 138 having a greater overall electrical resistance in the electrical resistance state 204 than in the electrical resistance state 202. The electrical resistance state 204 may be referred to as a medium high electrical resistance state.

As shown in FIG. 2D, in the electrical resistance state 206, a high resistance region 210 is located in the PCM layer 140 similar to the electrical resistance state 204. However, in the electrical resistance state 206, the high resistance region 210 is larger (e.g., occupies a greater area or volume of the PCM layer 140) than the high resistance region 210 in the electrical resistance state 204. Thus, in the electrical resistance state 206, the charge carriers propagate along a propagation path 216 through the first liner 144 and through the second liner 146 for a greater distance than along the propagation path 214 in the electrical resistance state 204. This results in the PCM device 138 having a greater overall electrical resistance in the electrical resistance state 206 than in the electrical resistance state 204. The electrical resistance state 206 may be referred to as a high electrical resistance state.

A set operation may be performed to transition the PCM layer 140 from the crystalline structural phase to an amorphous structural phase to form the high resistance region 210 (and/or to increase the size of the high resistance region 210) in the PCM layer 140 to transition the PCM device 138 from the electrical resistance state 200 to one of the electrical resistance states 202-206. A reset operation may be performed to transition the high resistance region 210 from the amorphous structural phase to the crystalline structural phase to reset the PCM device 138 to the electrical resistance state 200.

A set operation and a reset operation may each include providing a current (Iₕₑₐₜₑᵣ) to the metallization structure 130 coupled to the PCM device 138. The current causes the metallization structure 130 to function as a heater element in that the metallization structure 130 radiates heat toward the PCM layer 140 to increase the temperature of the PCM layer 140 to a particular temperature and for a particular time duration.

For a reset operation, the temperature of the PCM layer 140 may be increased from a baseline temperature (e.g., room temperature or a baseline operating temperature of the PCM layer 140 with the heater element off). The heat generated by the metallization structure 130 causes the temperature of the PCM layer 140 to increase from the baseline temperature. In particular, the temperature of the PCM layer 140 is quickly and rapidly increased to a reset temperature. The reset temperature is greater than a melting temperature of the PCM layer 140. Heating the PCM layer 140 such that the temperature of the PCM layer 140 increases to greater than the melting temperature of the PCM layer 140 causes the material of the PCM layer 140 to melt. An example of the melting temperature for a reset operation may be approximately 1000 degrees kelvin. However, other values for the melting temperature are within the scope of the present disclosure. The metallization structure 130 (e.g., the heater element) is subsequently deactivated, and the material of the PCM layer 140 is quenched such that the temperature of the PCM layer 140 rapidly decreases back to an ending temperature corresponding to the baseline temperature. The rapid heating (e.g., above the melting temperature) and cooling of the PCM layer 140 causes the material of the PCM layer 140 to transition from the crystalline structural phase to the amorphous structural phase.

For a set operation, the temperature of the PCM layer 140 is increased from the baseline temperature in a similar manner, except that the temperature of the PCM layer 140 is increased to and maintained at a set temperature. Moreover, the PCM layer 140 is maintained at the set temperature for a greater time duration than the reset temperature. For example, the time duration of the set operation may be on the order of a few microseconds (e.g., 1-5 microseconds), whereas the time duration of the reset operation may be on the order of nanoseconds (e.g., 100-200 nanoseconds). The set temperature is also less than the reset temperature. In particular, the set temperature is greater than a crystallization temperature of the material of the PCM layer 140 and less than the melting temperature of the material of the PCM layer 140. An example of the crystallization temperature may be approximately 500 degrees kelvin. However, other values for the crystallization temperature are within the scope of the present disclosure. Heating the PCM layer 140 to greater than the crystallization temperature of the material of the PCM layer 140 and less than the melting temperature of the material of the PCM layer 140 causes the material of the PCM layer 140 to crystalize (or recrystallize), which causes the material of the PCM layer 140 to transition from the amorphous structural phase to the crystalline structural phase. The metallization structure 130 (e.g., the heater element) is subsequently deactivated, and the material of the PCM layer 140 is quenched such that the temperature of the PCM layer 140 decreases back to the baseline temperature.

FIG. 2E illustrates the electrical resistance states 202-206 as a function of electrical resistance magnitude 218 and time 220. As shown in FIG. 2E, the electrical resistance states 202-206 may be separated by differences in electrical resistance magnitude 218. The difference in electrical resistance magnitude 218 between the electrical resistance state 202 and the electrical resistance state 206 is referred to as the memory window for the PCM device 138. The first liner 144 and the second liner 146 being formed of high resistivity material(s) (e.g., material(s) having a resistivity that is up to approximately 100 times the resistivity of the PCM of the PCM layer 140, or greater) provides for a larger memory window for the PCM device 138. The larger memory window provides for greater differences in electrical resistance magnitude 218 between the electrical resistance states 202-206, which reduces the likelihood of and/or the rate of memory errors for the PCM device 138.

As indicated above, FIGS. 2A-2E are provided as examples. Other examples may differ from what is described with regard to FIGS. 2A-2E.

FIGS. 3A-3D are diagrams of example attributes of materials included in one or more liners of a PCM device 138 described herein.

FIG. 3A illustrates an example 300 of resistivity 302 of a material of a liner (e.g., of a first liner 144, of a second liner 146) of a PCM device 138 described herein. The resistivity 302 of the material of the liner may depend at least in part on a hybridization composition 304 of carbon atoms in the material of the liner.

The hybridization composition of the carbon atoms in the material of the liner may include a combination of sp² carbon atoms 306 and sp³ carbon atoms 308. The sp² carbon atoms 306 are carbon atoms that have three sp² hybrid orbitals that are arranged in an approximately trigonal planar geometry (e.g., at approximately 120 degree bond angles). Each of the three sp² hybrid orbitals contains one s orbital and two p orbitals. The sp² carbon atoms 306 may be arranged in a two-dimensional crystal structure in the form of graphene.

The sp³ carbon atoms 308 are carbon atoms that have four sp³ hybrid orbitals that are arranged in an approximately tetrahedral geometry (e.g., at approximately 109.5 degree bond angles). Each of the four sp³ hybrid orbitals contains one s orbital and three p orbitals. The sp³ carbon atoms 308 may be arranged in a three-dimensional crystal structure having a diamond-like structure.

As further shown in FIG. 3A, the greater the concentration of sp³ carbon atoms 308 in the hybridization composition 304, the greater the resistivity 302 of the material of the liner. Conversely, the greater the concentration of sp² carbon atoms 306 in the hybridization composition 304, the lesser the resistivity 302 of the material of the liner. The concentrations of sp² carbon atoms 306 and sp³ carbon atoms 308 in the hybridization composition 304 of the material of the liner may be selected to achieve a resistivity in a range 310 that may correspond to approximately 0.01 ohm-meters to approximately 0.1 ohm-meters. However, other values and ranges for the resistivity 302 of the material of the liner are within the scope of the present disclosure.

FIG. 3B illustrates an example 312 in which the hybridization composition 304 (e.g., a ratio of sp³ carbon atoms 308 to sp² carbon atoms 306) of the material of the liner is dependent at least in part on a silicon (Si) concentration 314 in the material of the liner. In implementations in which the material of the liner contains silicon-doped carbon (C:Si), the greater the silicon concentration 314 in the material of the liner, the greater the ratio of sp³ carbon atoms 308 to sp² carbon atoms 306 in the material of the liner. The silicon atoms in the material of the liner replace carbon atoms in the crystal lattice of the material of the liner. The silicon atoms have a larger size than the carbon atoms, and the larger size of the silicon atoms may disrupt the sp² bonding of carbon atoms in the material of the liner. This can result in carbon atoms nearby the silicon atoms in the crystal lattice of the material of the liner adapting to sp³ bonding arrangements, thereby increasing the concentration of sp³ carbon atoms 308 in the material of the liner. Thus, increasing the silicon doping in the material of the liner may increase the concentration of sp³ carbon atoms 308 in the material of the liner, whereas reducing the silicon doping in the material of the liner may decrease the concentration of sp³ carbon atoms 308 in the material of the liner.

FIG. 3C illustrates an example 316 in which hybridization composition 304 (e.g., a ratio of sp³ carbon atoms 308 to sp² carbon atoms 306) of the material of the liner is dependent at least in part on a nitrogen (Ni) concentration 318 in the material of the liner. In implementations in which the material of the liner contains nitrogen-doped carbon (C:N), the greater the nitrogen concentration 318 in the material of the liner, the lesser the ratio of sp³ carbon atoms 308 to sp² carbon atoms 306 in the material of the liner. The nitrogen atoms in the material of the liner replace carbon atoms in the crystal lattice of the material of the liner. The nitrogen atoms have a greater quantity of valence electrons than the carbon atoms (e.g., five for nitrogen atoms compared to four for carbon atoms), and the additional valence electron contributes to the electron density in surrounding carbon atoms, which stabilizes and/or promotes formation of sp² hybridization. Thus, increasing the nitrogen doping in the material of the liner may increase the concentration of sp² carbon atoms 306 in the material of the liner, whereas reducing the nitrogen doping in the material of the liner may decrease the concentration of sp² carbon atoms 306 in the material of the liner.

FIG. 3D illustrates an example 320 of resistivity 302 of a material of a liner (e.g., of a first liner 144, of a second liner 146) of a PCM device 138 described herein relative to nitrogen concentration 322 in the material of the liner, where the material of the liner is a nitride such as aluminum nitride (AlN). The resistivity 302 of the material of the liner may depend at least in part on the nitrogen concentration 322 in that the greater the nitrogen concentration 322, the greater the resistivity 302, and the lower the nitrogen concentration 322, the lower the resistivity 302. The nitrogen concentration 322 in the nitride material of the liner may be selected to achieve a resistivity in a range 324 that may correspond to approximately 0.01 ohm-meters to approximately 0.1 ohm-meters. However, other values and ranges for the resistivity 302 of the material of the liner are within the scope of the present disclosure.

As indicated above, FIGS. 3A-3D are provided as examples. Other examples may differ from what is described with regard to FIGS. 3A-3D.

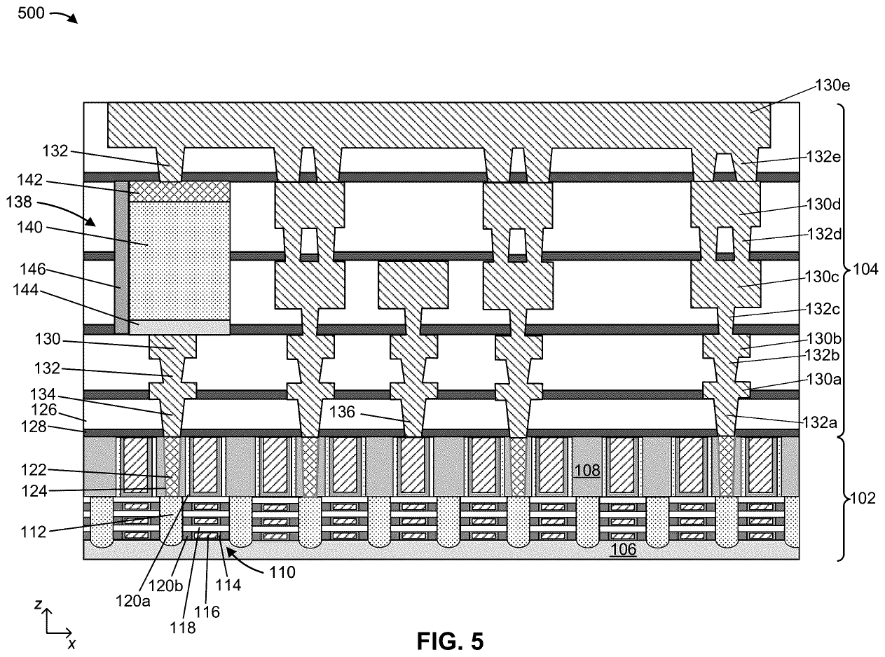

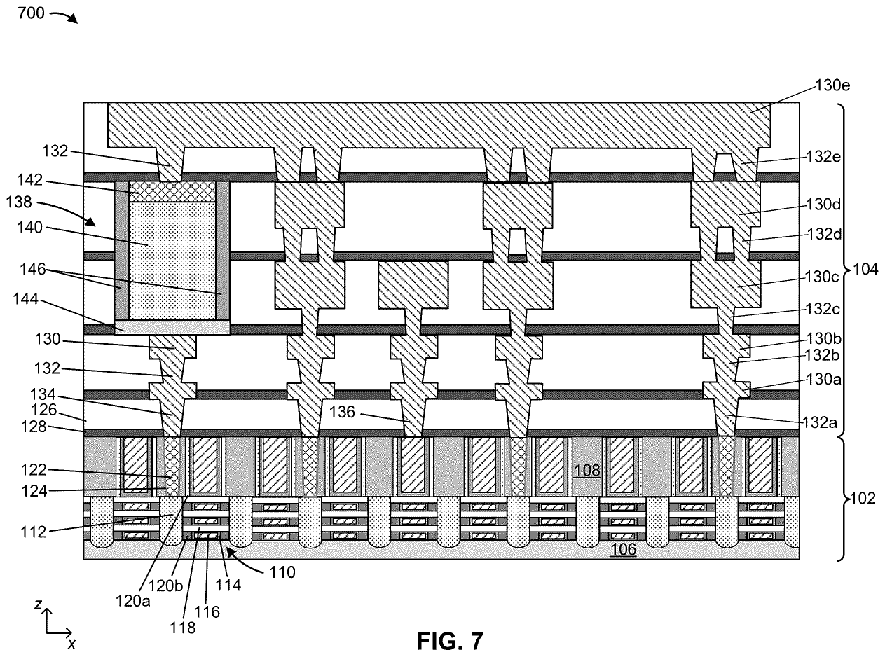

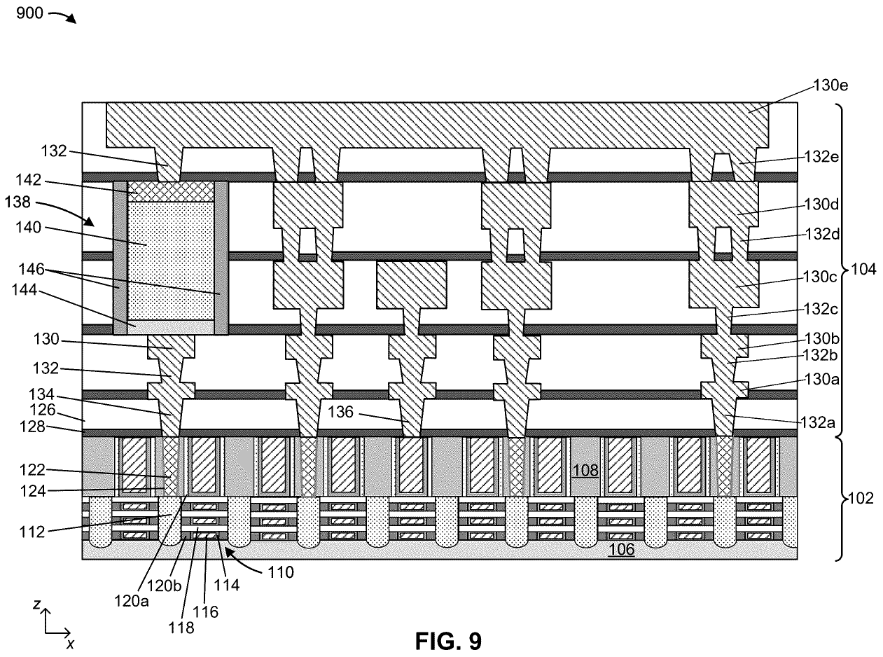

FIGS. 4A-4K are diagrams of an example implementation 400 of forming the semiconductor device 100 described herein. In some implementations, one or more of the semiconductor processing operations described in connection with FIGS. 4A-4K may be performed to form another semiconductor device described herein, such as a semiconductor device 500 illustrated in FIG. 5, a semiconductor device 700 illustrated in FIG. 7, and/or a semiconductor device 900 illustrated in FIG. 9, among other examples. In some implementations, one or more of the semiconductor processing operations described in connection with FIGS. 4A-4K may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 4A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

As further shown in FIG. 4A, a layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 402 and nanostructure channel layers 404 above the substrate layer 106. The quantity of the sacrificial layers 402 and the quantity of the nanostructure channel layers 404 illustrated in FIG. 4A are examples, and other quantities of the sacrificial layers 402 and the nanostructure channel layers 404 are within the scope of the present disclosure.

The sacrificial layers 402 enable a vertical distance to be defined between adjacent nanostructure channels that are formed from the nanostructure channel layers 404, and serve as placeholder layers for subsequently-formed gate structures of the integrated circuit devices 110 of the semiconductor device 100 that are formed around the nanostructure channels.

The sacrificial layers 402 include a first material composition, and the nanostructure channel layers 404 include a second material composition. In some implementations, the first material composition and the second material composition are the same material composition. In some implementations, the first material composition and the second material composition are different material compositions. As an example, the sacrificial layers 402 may include silicon germanium (SiGe) and the nanostructure channel layers 404 may include silicon (Si). This enables the sacrificial layers 402 and/or the nanostructure channel layers 404 to be selectively etched (e.g., enables the sacrificial layers 402 and not the nanostructure channel layers 404 to be etched, enables the nanostructure channel layers 404 and not the sacrificial layers 402 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 402 and/or the nanostructure channel layers 404 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 402 and/or the nanostructure channel layers 404 may be deposited by chemical vapor deposition (CVD), physical vapor deposition (PVD), atomic layer deposition (ALD), and/or another suitable deposition technique.

In the y-direction, which is not visible in the view in FIG. 4A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 4B, dummy gate structures 406 (also referred to as dummy gate stacks or temporary gate structures) may be formed over portions of the layer stack of sacrificial layers 402 and nanostructure channel layers 404. The dummy gate structures 406 may extend in the y-direction and may be arranged in the x-direction such that the dummy gate structures 406 are approximately perpendicular to the fin structures. The dummy gate structures 406 are sacrificial structures that are to be replaced by replacement gate structures or replacement gate stacks at a subsequent processing stage for the integrated circuit devices 110 of the semiconductor device 100. The dummy gate structures 406 may also be used to define source/drain (S/D) recesses in which source/drain regions of the nanostructure transistors are formed in the layer stack of sacrificial layers 402 and nanostructure channel layers 404.

The dummy gate structures 406 may include polycrystalline silicon (polysilicon or PO) or another material. The layers of the dummy gate structures 406 may be formed using various semiconductor processing techniques such depositing the layers of the dummy gate structures 406 patterning the layers of the dummy gate structures 406 to define the dummy gate structures 406, and/or other semiconductor processing techniques. The sidewall spacers 120a may be formed on the sidewalls of the dummy gate structures 406.

As shown in FIG. 4C, the source/drain regions 112 of the integrated circuit devices 110 are formed in the layer stack of sacrificial layers 402 and nanostructure channel layers 404. To form the source/drain regions 112, source/drain recesses may be formed through the layer stack of sacrificial layers 402 and nanostructure channel layers 404 in an etch operation. The source/drain recesses may be formed on opposing sides of a dummy gate structure 406 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 402 that are exposed in the source/drain recesses may be laterally etched in an etch operation, thereby forming cavities in the ends of the sacrificial layers 402. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 4C, the dielectric layer 108 may be formed over the source/drain regions 112 and around the dummy gate structures 406. The dielectric layer 108 may fill in areas between the dummy gate structures 406. In some implementations, a contact etch stop layer (CESL) is conformally deposited (e.g., using a deposition tool) over the source/drain regions 112 prior to formation of the dielectric layer 108. The dielectric layer 108 is then formed on the CESL. The CESL may provide a mechanism to stop an etch process when forming source/drain contacts 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 4D, a replacement gate process may be performed to replace the dummy gate structures 406 with the gate structures 116 of the integrated circuit devices 110. A dummy gate removal operation may be performed to remove the dummy gate structures 406 from the semiconductor device 100. The removal of the dummy gate structures 406 leaves behind openings (or recesses) in the dielectric layer 108, and provides access to the underlying sacrificial layers 402. The dummy gate structures 406 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 402 (e.g., the silicon germanium layers). This results in openings between the channel layers 118 (e.g., the areas around the channel layers 118). The sacrificial layers 402 may be removed through the spaces that were previously occupied by the dummy gate structures 406. The nanostructure release operation may include the use of an etch tool to perform an etch operation to remove the sacrificial layers 402 based on a difference in etch selectivity between the material of the sacrificial layers 402 and the material of the channel layers 118, and between the material of the sacrificial layers 402 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 402 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 406. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 4D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a chemical-mechanical planarization (CMP) operation) to planarize the source/drain contact structures 122 after the source/drain contact structures 122 are deposited such that the tops of the source/drain contact structures 122 are approximately co-planar with the top of the dielectric layer 108.

As shown in FIG. 4E, a first portion of the interconnect layer 104 of the semiconductor device 100 is formed above the device layer 102. One or more deposition tools are used to deposit alternating layers of ILD layers 126 and ESLs 128 in the interconnect layer 104 of the semiconductor device 100. In this way, the ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

As further shown in FIG. 4E, a plurality of layers of conductive structures may be formed in the dielectric layers of the interconnect layer 104. For example, a deposition tool, an exposure tool, a developer tool, an etch tool, a planarization tool, a plating tool, and/or another semiconductor processing tool may be used to perform various operations to form the source/drain interconnect structures 134 and/or the gate interconnect structures 136 at the bottom of the interconnect layer 104. One or more source/drain interconnect structures 134 may be formed on one or more source/drain contact structures 122 of one or more integrated circuit devices 110. One or more gate interconnect structures 136 may be formed on one or more gate structures 116 of one or more integrated circuit devices 110.

A deposition tool, an exposure tool, a developer tool, an etch tool, a planarization tool, a plating tool, and/or another semiconductor processing tool may be used to perform various operations to form the source/drain interconnect structures 134, the gate interconnect structures 136, the metallization structures 130, and/or the interconnect structures 132 in the interconnect layer 104 of the semiconductor device 100. In some implementations, the interconnect layer 104 may be formed in a plurality of layers. For example, an ILD layer 126 and an ESL 128 may be formed (e.g., using one or more deposition tools and/or one or more planarization tools), recesses may be formed in and/or through the ILD layer 126 and the ESL 128 (e.g., using an exposure tool, a developer tool, and/or an etch tool), and a layer (e.g., the V0 layer) of interconnect structures 132a, including the source/drain interconnect structures 134 and/or the gate interconnect structures 136, may be formed in the recesses (e.g., using one or more deposition tools and/or one or more planarization tools). Another ILD layer 126 and another ESL 128 may be formed, and a layer (e.g., the M0 layer) of metallization structures 130a may be formed in the recesses. Additional layers of metallization structures 130b and additional layers of interconnect structures 132b may be formed in a similar manner.

One or more deposition tools may be used to deposit the source/drain interconnect structures 134, the gate interconnect structures 136, the metallization structures 130, and/or the interconnect structures 132 using a PVD technique, an ALD technique, a CVD technique, an electroplating technique (e.g., an electro-chemical plating technique), and/or another suitable deposition technique. In some implementations, a planarization tool may be used to planarize the source/drain interconnect structures 134, the gate interconnect structures 136, the metallization structures 130, and/or the interconnect structures 132 after the source/drain interconnect structures 134, the gate interconnect structures 136, the metallization structures 130, and/or the interconnect structures 132 are deposited.

As shown in FIG. 4F, a layer stack may be formed over the first portion of the interconnect layer 140 of the semiconductor device 100. The layer stack may include a layer 408, a layer 410 over and/or on the layer 408, and a layer 412 over and/or on the layer 410. The layer 408 may be a layer from which the first liner 144 of the PCM device 138 is to be formed. The layer 410 may be a layer from which the PCM layer 140 of the PCM device 138 is to be formed. The layer 412 may be a layer from which the electrode layer 142 of the PCM device 138 is to be formed.

One or more deposition tools may be used to deposit the layers 408-412 using a PVD technique, an ALD technique, a CVD technique, an electroplating technique, and/or another suitable deposition technique. In some implementations, a planarization tool may be used to planarize the layers 408-412 after the layers 408-412 are deposited.

As shown in FIG. 4G, a patterned masking layer 414 may be formed over and/or on the layer stack. In some implementations, the patterned masking layer 414 includes a photoresist layer. In these implementations, a deposition tool may be used to form the photoresist layer on the layer 412 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. In some implementations, the pattern in the photoresist layer may be transferred to a masking layer formed on the layer 412 by etching the masking layer to define the patterned masking layer 414.

As shown in FIG. 4H, an etch tool may be used to etch one or more layers of the layer stack based on the pattern to define the electrode layer 142 of the PCM device 138 from the layer 412, and/or to define the PCM layer 140 of the PCM device 138 from the layer 410. In some implementations, the etch operation includes a dry etch operation (e.g., a plasma-based etch operation, a gas-based etch operation), a wet chemical etch operation, and/or another type of etch operation. A plasma-based etch technique may be used to anisotropically etch the layers 410 and 412. The use of the plasma-based etch technique minimizes lateral etching (and thus, undercutting) of the layers 410 and 412, resulting in substantially vertical sidewalls for the PCM layer 140 and for the electrode layer 142. However, because of the use of plasma as an etchant, the plasma-based etch technique may result in some etching to portions of the layer 408 that are not underneath the PCM layer 140. Thus, the first liner 144 that is to be formed from the layer 408 may have recessed or curved end portions (e.g., as shown in the examples in FIGS. 1C and 1D) after the layer 408 is subsequently etched to define the first liner 144.

As shown in FIG. 4I, a layer 416 may be deposited over the exposed portions of the layer 408, over the patterned masking layer 414, on the sidewalls of the PCM layer 140, and on the sidewalls of the electrode layer 142. In implementations in which the exposed portions of the layer 408 are recessed relative to the portion under the PCM layer 140, the material of the layer 416 may be deposited in the recessed portions of the layer 408.

The layer 416 may be a layer from which the second liner 146 is to be defined. The layer 408 and the layer 416 may include the same material, or may include different materials. A deposition tool may be used to deposit the layer 416 using a conformal deposition technique such as CVD and/or ALD. However, other deposition techniques may be used to deposit the material of the layer 416.

As shown in FIG. 4J, the layers 408 and 416 may be etched to respectively define the first liner 144 and the second liner 146. In some implementations, the etch operation includes a dry etch operation (e.g., a plasma-based etch operation, a gas-based etch operation), a wet chemical etch operation, and/or another type of etch operation. A plasma-based etch technique may be used to anisotropically etch the layers 408 and 416. The use of the plasma-based etch technique minimizes lateral etching of the layer 416 (and thus, removal of the layer 416 from the sidewalls of the PCM device 138), resulting in remaining portions of the layer 416 on the sidewalls of the PCM device 138 corresponding to the second liner 146. The etch of the layer 408 may be self-aligned in that the PCM layer 140 and the second liner 146 function as a self-aligned mask that protects the portion of the layer 408 under the PCM layer 140 and the second liner 146 from being etched. In this way, the portion of the layer 408 under the PCM layer 140 and the second liner 146 remains as the first liner 144.

As further shown in FIG. 4J, the second liner 146 may include a plurality of segments. A first segment of the second liner 146 may be located on a first sidewall of the PCM layer 140, and a second segment of the second liner 146 may be located on a second sidewall of the PCM layer 140 opposing the first sidewall. The operations illustrated and described in connection with FIGS. 4K-4L may be performed to remove one of the segments of the second liner 146 such that the second liner 146 includes only one of the segments on one of the sidewalls of the PCM layer 140, so that the first liner 144 and the second liner 146 form an L-shape. In other implementations described herein, the operations illustrated and described in connection with FIGS. 4K-4L may be omitted so that the first liner 144 and the second liner 146 form a U-shape around the PCM layer 140, such as illustrated in FIGS. 7 and 9.

As shown in FIG. 4K, another masking layer 418 may be formed over the first portion of the interconnect layer 104, and over the PCM device 138. The masking layer 418 may include a photoresist layer and/or another type of masking layer. A deposition tool may be used to deposit the material of the masking layer 418 using a spin-coating technique and/or another suitable deposition technique.

As shown in FIG. 4L, recess 420 may be formed through the masking layer 418 to expose one of the segments of the second liner 146 on one of the sidewalls of the PCM layer 140. An exposure tool may be used to expose the masking layer 418 to a radiation source to pattern the masking layer 418. A developer tool may be used to develop and remove portions of the masking layer 418 to expose the pattern, resulting in formation of the recess 420.

As shown in FIG. 4M, an etch operation may be performed to remove the exposed segment of the second liner 146. In some implementations, a portion of the first liner 144 under the segment of the second liner 146 is also removed in the etch operation. An etch tool may be used to perform the etch operation. An etch technique, such as a dry etch and/or a wet etch, may be performed to remove the segment of the second liner 146 and/or the portion of the first liner 144 under the segment of the second liner 146.

As shown in FIG. 4N, the remaining portions of the masking layer 418 may be removed from the semiconductor device 100 after removing the segment of the second liner 146 and/or the portion of the first liner 144 under the segment of the second liner 146. For example, an ashing operation (e.g., a plasma ashing operation) may be performed to remove the remaining portions of the masking layer 418. As another example, the remaining portions of the masking layer 418 may be removed using a chemical stripper.

As shown in FIG. 4O, additional dielectric layers of the interconnect layer 104 may be formed around the PCM device 138. For example, one or more deposition tools are used to deposit additional alternating layers of ILD layers 126 and ESLs 128 in the interconnect layer 104 of the semiconductor device 100 using a PVD technique, an ALD technique, a CVD technique, an oxidation technique, and/or another suitable deposition technique. In some implementations, a planarization tool may be used to planarize the additional ILD layers 126 and/or the additional ESLs 128.

As further shown in FIG. 4O, additional conductive structures may be formed in the additional dielectric layers laterally adjacent to the PCM structure 138 in the interconnect layer 104. For example, the layer of interconnect structures 132c, the layer of metallization structures 130c, the layer of interconnect structures 132d, and/or the layer of metallization structures 130d may be formed in the additional dielectric layers.

As shown in FIG. 4P, additional dielectric layers of the interconnect layer 104 may be formed above and/or over the PCM device 138. For example, one or more deposition tools are used to deposit additional alternating layers of ILD layers 126 and ESLs 128 in the interconnect layer 104 of the semiconductor device 100 using a PVD technique, an ALD technique, a CVD technique, an oxidation technique, and/or another suitable deposition technique. In some implementations, a planarization tool may be used to planarize the additional ILD layers 126 and/or the additional ESLs 128.

As shown in FIG. 4Q, additional conductive structures may be formed in the additional dielectric layers above the PCM structure 138 in the interconnect layer 104. For example, the layer of interconnect structures 132e and/or the layer of metallization structures 130e may be formed in the additional dielectric layers. One or more of the interconnect structures 132 in the layer of interconnect structures 132e may be formed over and/or on the electrode layer 142 of the PCM structure 138 such that the one or more of the interconnect structures 132 are electrically coupled and/or physically coupled to the electrode layer 142.

As indicated above, FIGS. 4A-4Q are provided as an example. Other examples may differ from what is described with regard to FIGS. 4A-4Q.

FIG. 5 is a diagram of a portion of an example semiconductor device 500 described herein. As shown in FIG. 5, the semiconductor device 500 may be similar to the semiconductor device 100, and may include a similar combination and arrangement of layers and/or structures as the semiconductor device 100.

However, the PCM device 138 in the semiconductor device 500 may include a second liner 146 that extends alongside the first liner 144 as opposed to being located on a portion of the first liner 144 that extends laterally outward from the PCM layer 140 of the PCM device 138. Thus, the first liner 144 in the semiconductor device 500 may be contained within a footprint of the PCM layer 140, and a portion of a sidewall of the second liner 146 may be in contact with an end of the first liner 144. The bottom end (or bottom surface) of the second liner 146 may be in contact with one or more of the dielectric layers included in the interconnect layer 104, and may be approximately co-planar with a bottom surface of the first liner 144. The interface between the first liner 144 and the second liner 146 may be substantially vertical, or may be scalloped or have a small amount of recessing due to lateral etching of the first liner 144.

As indicated above, FIG. 5 is provided as an example. Other examples may differ from what is described with regard to FIG. 5.

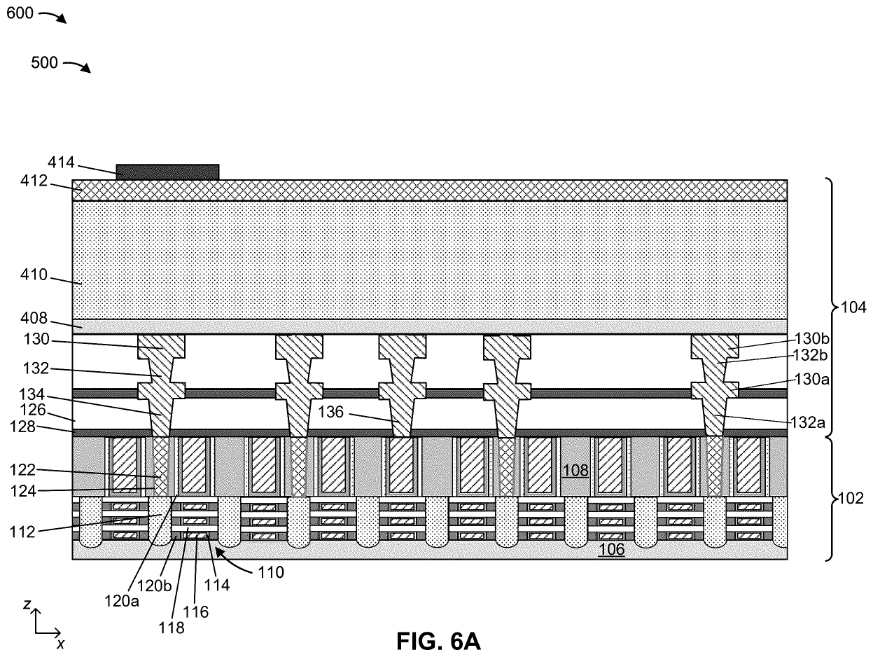

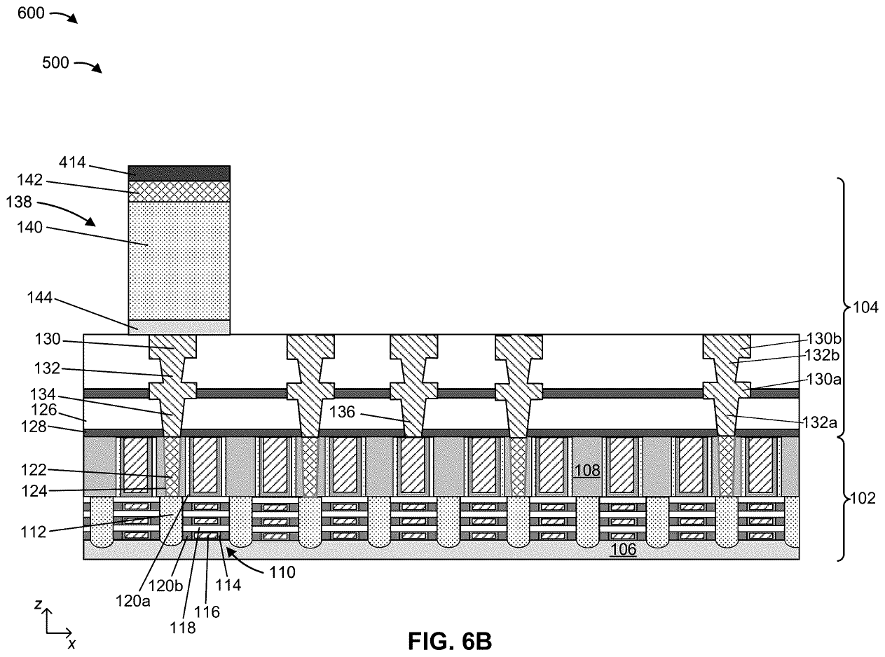

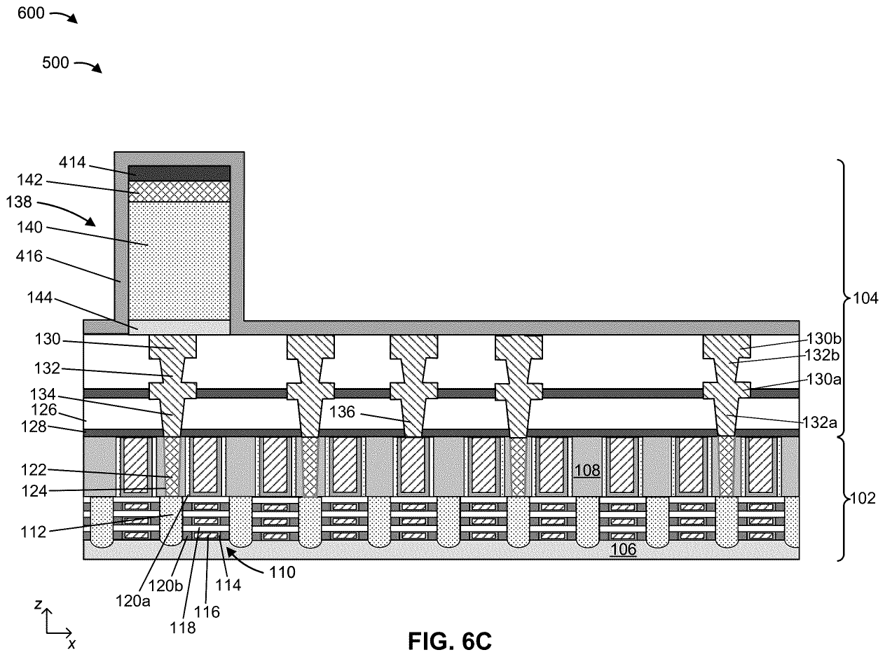

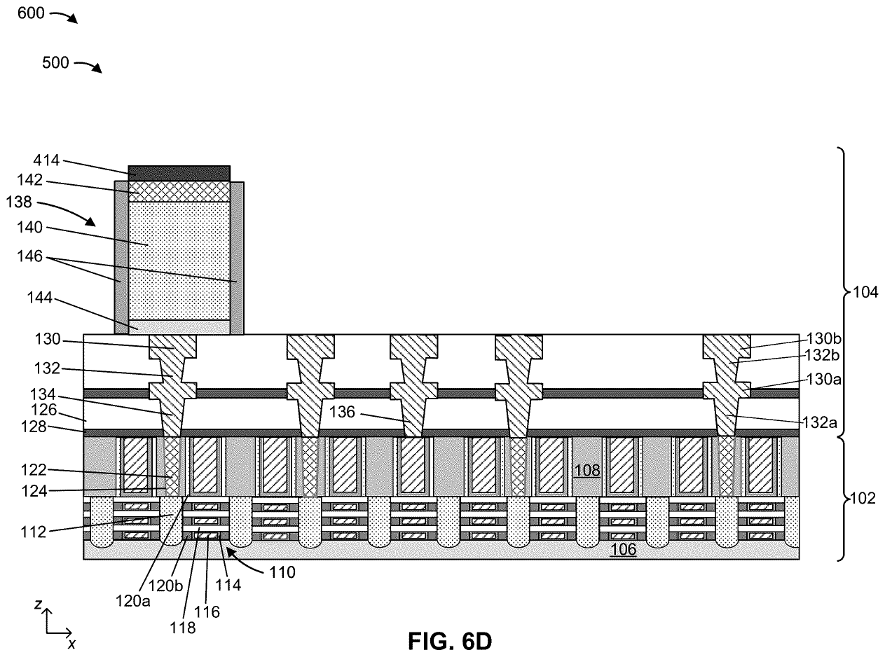

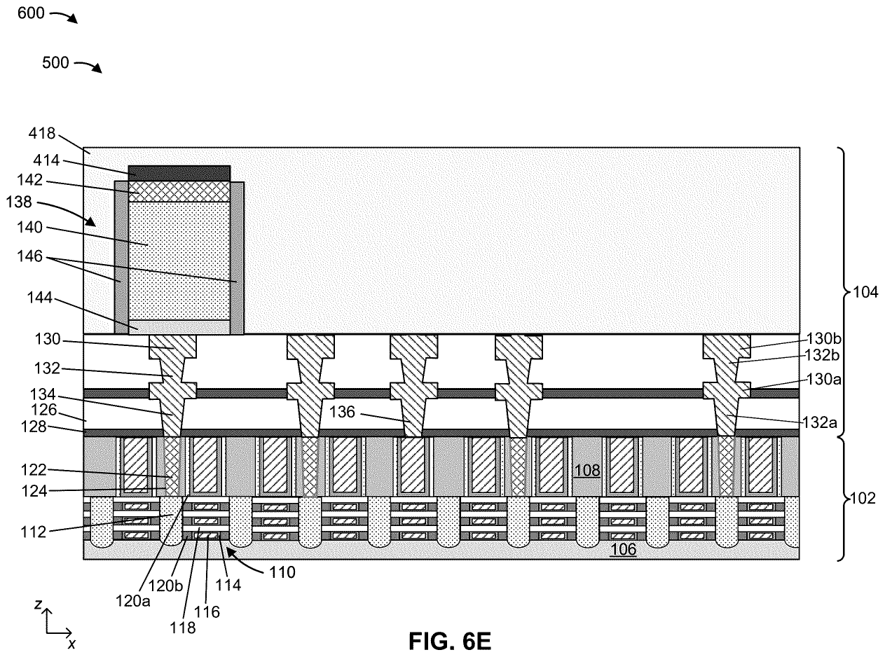

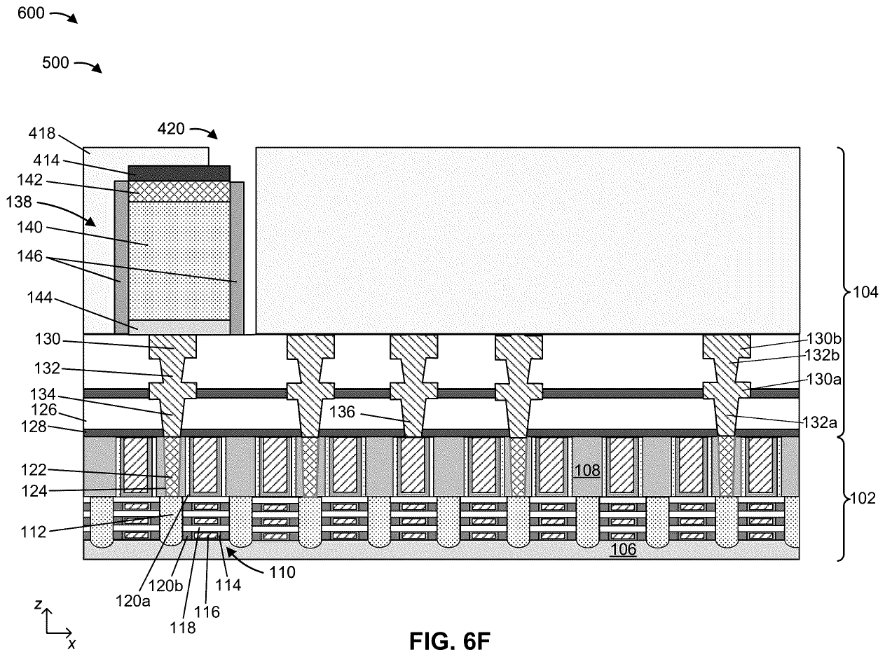

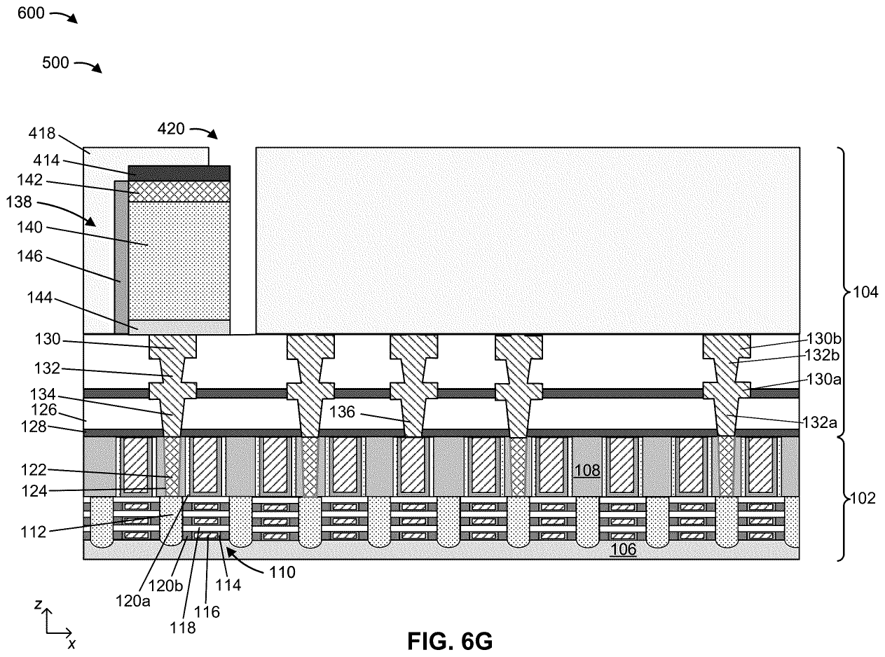

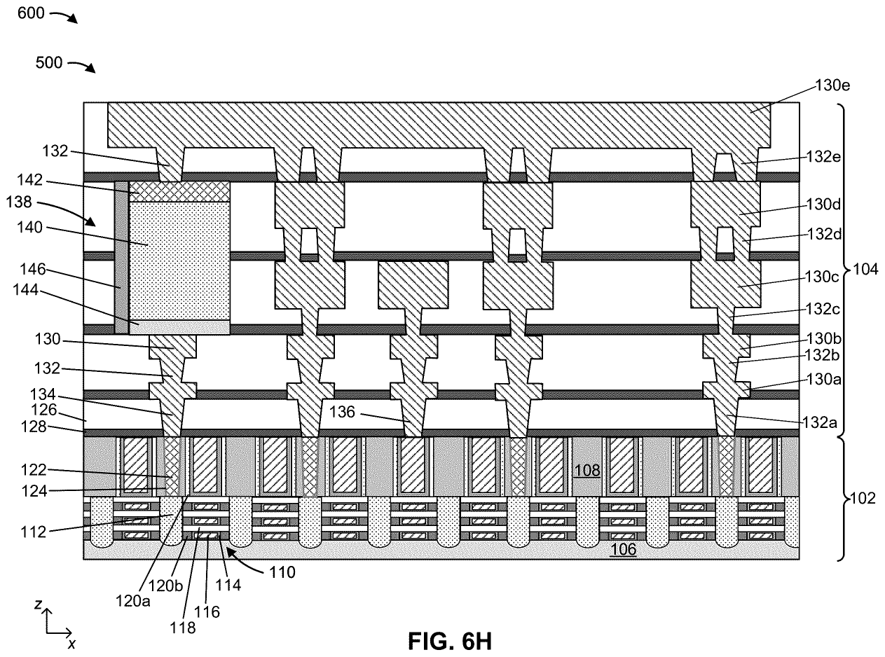

FIGS. 6A-6H are diagrams of an example implementation 600 of forming the semiconductor device 500 described herein. In some implementations, one or more of the semiconductor processing operations described in connection with FIGS. 6A-6H may be performed to form another semiconductor device described herein, such as a semiconductor device 100 illustrated in FIG. 1, a semiconductor device 700 illustrated in FIG. 7, and/or a semiconductor device 900 illustrated in FIG. 9, among other examples. In some implementations, one or more of the semiconductor processing operations described in connection with FIGS. 6A-6H may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 6A, similar operations as illustrated and described in connection with FIGS. 4A-4G to form the integrated circuit devices 110 in the device layer 102, to form the first portion of the interconnect layer 104, to form the layer stack of the layers 408-412, and/or to form the patterned masking layer 414 may be performed.

As shown in FIG. 6B, the patterned masking layer 414 may be used to perform an etch operation to etch the layers 410 and 412 to respectively form the PCM layer 140 and the electrode layer 142 in a similar manner as described in connection with FIG. 4H. However, in the example implementation 600, the layer 408 is also etched in the same etch operation as the layers 410 and 412 to define the first liner 144. Thus, the example implementation 600 differs from the example implementation 400 in that the first liner 144 is defined along with the PCM layer 140 and the electrode layer 142 in the example implementation 600, as opposed to the first liner 144 being defined from the layer 408 along with the second liner 146 being subsequently defined from the layer 416 in the example implementation 400.

As shown in FIG. 6C, the layer 416 may be formed in a similar manner as described in connection with FIG. 4I. However, in the example implementation 600, the layer 416 may be formed on the top-most dielectric layer of the interconnect layer as opposed to being formed on the layer 408. Thus, portions of the layer 416 are formed on sidewalls of the first liner 144.

As shown in FIG. 6D, the layer 416 may be etched in a similar manner as described in connection with FIG. 4J. However, in the example implementation 600, only the layer 416 is etched, and the segments of the second liner 146 protect the first liner 144 from being etched along with the layer 416.

As shown in FIG. 6E, the masking layer 418 may be formed in a similar manner as described in connection with FIG. 4K. As shown in FIG. 6F, the recess 420 may be formed through the masking layer 418 to expose a segment of the second liner 146 on a sidewall of the PCM layer 140 in a similar manner as described in connection with FIG. 4L. As shown in FIG. 6G, an etch operation may be performed to remove the exposed segment of the second liner 146 from the sidewall of the PCM layer 140 in a similar manner as described in connection with FIG. 4M. However, in the example implementation 600, the exposed segment of the second liner 146 protects the first liner 144 during the etch operation. However, a small amount of etching of the end of the first liner 144 may occur, resulting in the end of the first liner 144 becoming recessed. The masking layer 418 may be subsequently removed in a similar manner as described in connection with FIG. 4N.

As shown in FIG. 6H, additional dielectric layers (e.g., additional ILD layers 126, additional ESLs 128), additional metallization structures 130, and/or additional interconnect structures 132 may be formed in a similar manner as illustrated and described in connection with FIG. 4O-4Q.

As indicated above, FIGS. 6A-6H are provided as an example. Other examples may differ from what is described with regard to FIGS. 6A-6H.

FIG. 7 is a diagram of a portion of an example semiconductor device 700 described herein. As shown in FIG. 7, the semiconductor device 700 may be similar to the semiconductor device 100, and may include a similar combination and arrangement of layers and/or structures as the semiconductor device 100.

However, a plurality of segments of the second liner 146 may be retained in the PCM device 138 in the semiconductor device 700. Thus, the second liner 146 in the semiconductor device 700 may include a first segment on a first sidewall of the PCM layer 140 and a second segment on an opposing second sidewall of the PCM layer 140. A bottom end or bottom surface of the first segment of the second liner 146 may be on top of and in contact with a first end of the first liner 144, and a bottom end or bottom surface of the second segment of the second liner 146 may be on top of and in contact with an opposing second end of the first liner 144. The first liner 144 and the second liner 146 may therefore form a U-shaped cross-sectional profile in the PCM device 138. The second segment of the second liner 146 may provide another propagation path for charge carriers in the PCM device 138 so that charge carriers can propagate through a plurality of segments of the second liner 146 to the PCM layer 140.

As indicated above, FIG. 7 is provided as an example. Other examples may differ from what is described with regard to FIG. 7.

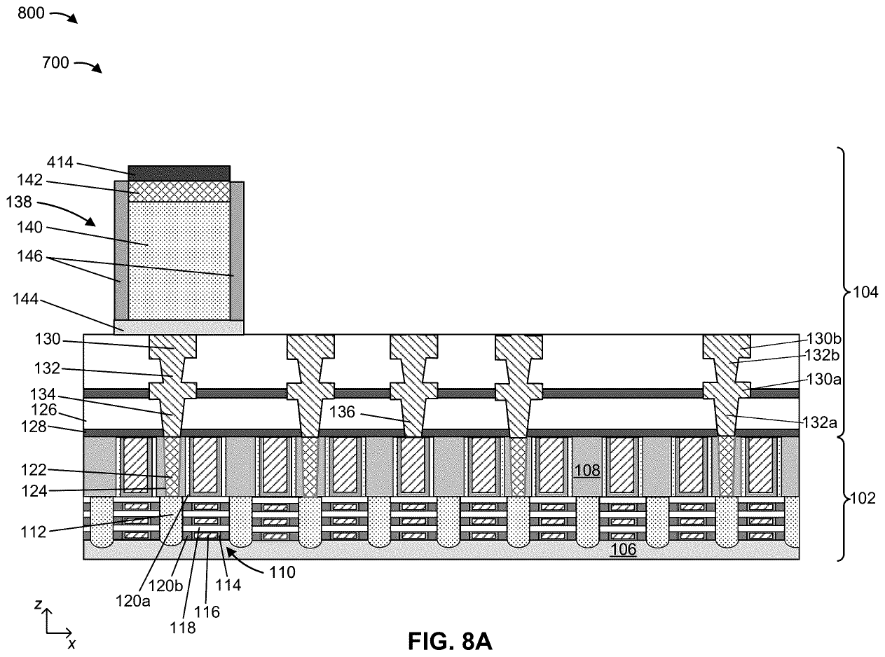

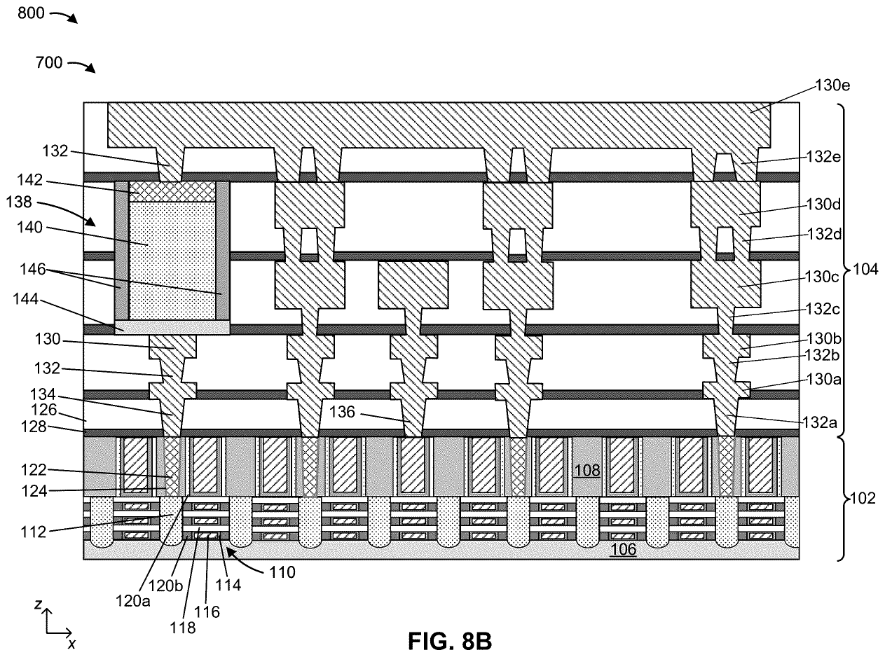

FIGS. 8A and 8B are diagrams of an example implementation 800 of forming the semiconductor device 700 described herein. In some implementations, one or more of the semiconductor processing operations described in connection with FIGS. 8A and 8B may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 8A, similar operations as illustrated and described in connection with FIGS. 4A-4J to form the integrated circuit devices 110 in the device layer 102, to form the first portion of the interconnect layer 104, and/or to form the PCM layer 140 to include the plurality of segments of the second liner 146 may be performed.

As shown in FIG. 8B, additional dielectric layers (e.g., additional ILD layers 126, additional ESLs 128), additional metallization structures 130, and/or additional interconnect layers 132 may be formed in a similar manner as illustrated and described in connection with FIG. 4O-4Q. In other words, the operations illustrated and described in connection with FIGS. 4K-4L may be omitted from the example implementation 800 so that the plurality of segments of the second liner 146 are retained, and so that the first liner 144 and the second liner 146 form a U-shape around the PCM layer 140.

As indicated above, FIGS. 8A and 8B are provided as an example. Other examples may differ from what is described with regard to FIGS. 8A and 8B.

FIG. 9 is a diagram of a portion of an example semiconductor device 900 described herein. As shown in FIG. 9, the semiconductor device 900 may be similar to the semiconductor device 500, and may include a similar combination and arrangement of layers and/or structures as the semiconductor device 500.

However, a plurality of segments of the second liner 146 may be retained in the PCM device 138 in the semiconductor device 700. Thus, the second liner 146 in the semiconductor device 700 may include a first segment on a first sidewall of the PCM layer 140 and a second segment on an opposing second sidewall of the PCM layer 140. A portion of a sidewall of the first segment of the second liner 146 may be in contact with a first end of the first liner 144, and a portion of a sidewall of the second segment of the second liner 146 may be in contact with an opposing second end of the first liner 144. The first liner 144 and the second liner 146 may therefore form a U-shaped cross-sectional profile in the PCM device 138. The second segment of the second liner 146 may provide another propagation path for charge carriers in the PCM device 138 so that charge carriers can propagate through a plurality of segments of the second liner 146 to the PCM layer 140.

As indicated above, FIG. 9 is provided as an example. Other examples may differ from what is described with regard to FIG. 9. It is to be noted that two or more of the implementations of PCM devices 138 illustrated in FIGS. 1A-1C, 5, 7, and/or 9 may be included in the same semiconductor device.

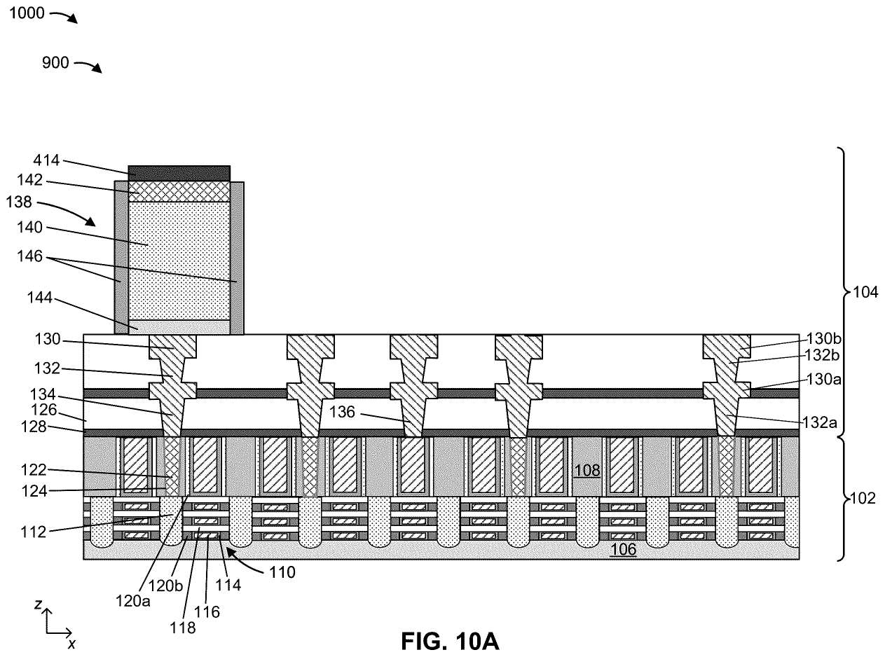

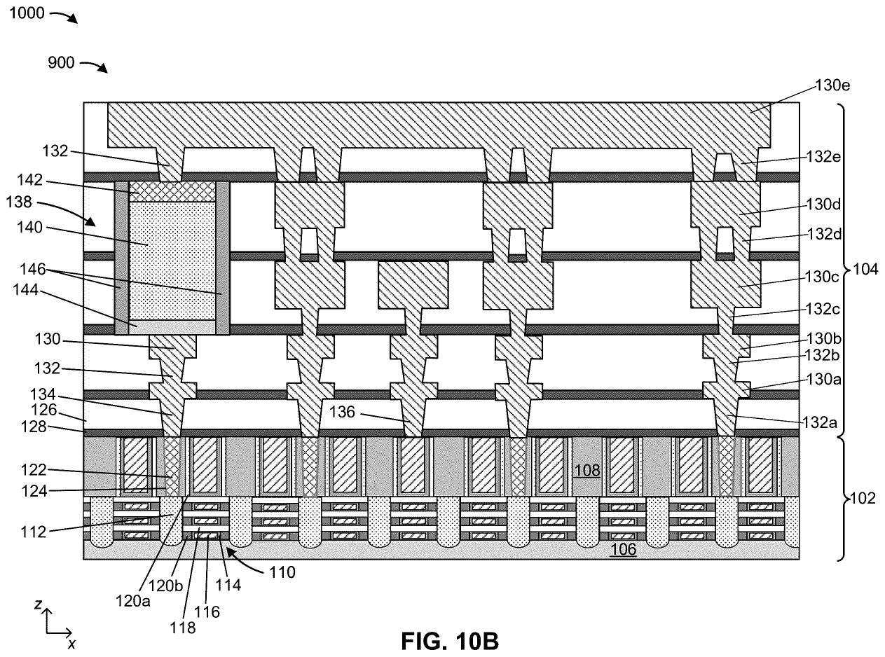

FIGS. 10A and 10B are diagrams of an example implementation 1000 of forming the semiconductor device 700 described herein. In some implementations, one or more of the semiconductor processing operations described in connection with FIGS. 10A and 10B may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 10A, similar operations as illustrated and described in connection with FIGS. 6A-6D to form the integrated circuit devices 110 in the device layer 102, to form the first portion of the interconnect layer 104, and/or to form the PCM layer 138 to include the plurality of segments of the second liner 146 may be performed.

As shown in FIG. 10B, additional dielectric layers (e.g., additional ILD layers 126, additional ESLs 128), additional metallization structures 130, and/or additional interconnect layers 132 may be formed in a similar manner as illustrated and described in connection with FIG. 6H. In other words, the operations illustrated and described in connection with FIGS. 6E-6G may be omitted from the example implementation 1000 so that the plurality of segments of the second liner 146 are retained, and so that the first liner 144 and the second liner 146 form a U-shape around the PCM layer 140.

As indicated above, FIGS. 10A and 10B are provided as an example. Other examples may differ from what is described with regard to FIGS. 10A and 10B.

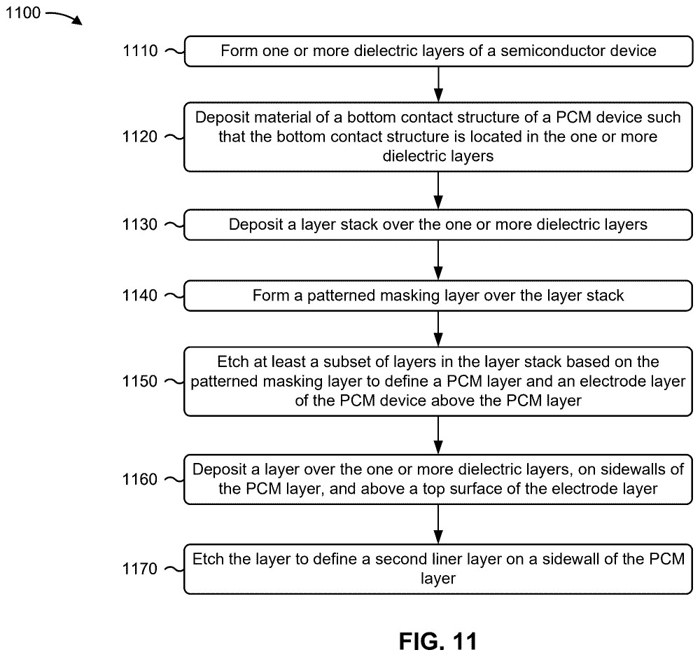

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming one or more dielectric layers of a semiconductor device (block 1110). For example, one or more semiconductor processing tools may be used to form one or more dielectric layers (e.g., one or more ILD layers 126, one or more ESLs 128) of a semiconductor device (e.g., a semiconductor device 100, a semiconductor device 500, a semiconductor device 700, a semiconductor device 900), as described herein.

As further shown in FIG. 11, process 1100 may include depositing material of a bottom contact structure of a PCM device such that the bottom contact structure is located in the one or more dielectric layers (block 1120). For example, one or more semiconductor processing tools may be used to deposit material of a bottom contact structure (e.g., a metallization structure 130, an interconnect structure 132) of a PCM device (e.g., a PCM device 138) such that the bottom contact structure is located in the one or more dielectric layers, as described herein.

As further shown in FIG. 11, process 1100 may include depositing a layer stack over the one or more dielectric layers (block 1130). For example, one or more semiconductor processing tools may be used to deposit a layer stack (e.g., layers 408, 410, and/or 412) over the one or more dielectric layers, as described herein.

As further shown in FIG. 11, process 1100 may include forming a patterned masking layer over the layer stack (block 1140). For example, one or more semiconductor processing tools may be used to form a patterned masking layer (e.g., a patterned masking layer 414) over the layer stack, as described herein.

As further shown in FIG. 11, process 1100 may include etching at least a subset of layers in the layer stack based on the patterned masking layer to define a PCM layer and an electrode layer of the PCM device above the PCM layer (block 1150). For example, one or more semiconductor processing tools may be used to etch at least a subset of layers in the layer stack based on the patterned masking layer to define a PCM layer (e.g., a PCM layer 140) and an electrode layer (e.g., an electrode layer 142) of the PCM device above the PCM layer, as described herein. In some implementations, the PCM layer and the electrode layer are located above the bottom contact structure. In some implementations, a first liner layer (e.g., a first liner 144) of the PCM device is located between the PCM layer and the bottom contact structure.

As further shown in FIG. 11, process 1100 may include depositing a layer over the one or more dielectric layers, on sidewalls of the PCM layer, and above a top surface of the electrode layer (block 1160). For example, one or more semiconductor processing tools may be used to deposit a layer (e.g., a layer 416) over the one or more dielectric layers, on sidewalls of the PCM layer, and above a top surface of the electrode layer, as described herein.

As further shown in FIG. 11, process 1100 may include etching the layer to define a second liner layer on a sidewall of the PCM layer (block 1170). For example, one or more semiconductor processing tools may be used to etch the layer to define a second liner layer (e.g., a second liner 146) on a sidewall of the PCM layer, as described herein.

Process 1100 may include additional implementations, such as any single implementation or any combination of implementations described below and/or in connection with one or more other processes described elsewhere herein.

In a first implementation, etching the at least the subset of the layer stack includes etching the layer stack to define the first liner layer from the layer stack.

In a second implementation, alone or in combination with the first implementation, depositing the layer includes depositing the layer such that the layer contacts ends of the first liner layer.

In a third implementation, alone or in combination with one or more of the first and second implementations, etching the layer to define the second liner layer includes etching the layer and another layer of the layer stack to define the second liner layer from the layer and to define the first liner layer from the other layer of the layer stack.

In a fourth implementation, alone or in combination with one or more of the first through third implementations, process 1100 includes forming another masking layer (e.g., a masking layer 418) over the PCM device after etching the layer to define the second liner layer, forming a recess (e.g., a recess 420) through the other masking layer such that a first segment of the second liner layer on a first sidewall of the PCM layer is exposed in the recess, and etching the first segment to remove the first segment from the first sidewall of the PCM layer, wherein a second segment of the second liner layer remains on a second sidewall of the PCM layer.

In a fifth implementation, alone or in combination with one or more of the first through fourth implementations, the first liner layer and the second liner layer are formed of different materials.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a PCM device may be manufactured for linear operation to achieve a high level of accuracy and reliability in the electrical resistance states of the PCM device for multi-bit operation. The PCM device may be manufactured to include a two-piece liner arrangement that includes a first liner between a PCM layer and a bottom contact structure of the PCM device, and a second liner on at least one sidewall of the PCM layer. The two-piece liner arrangement may be formed by depositing and patterning different layers. Thus, the first liner and the second liner are formed from the different layers. This enables attributes such as material, thickness, and/or electrical resistance of the first and second liners to be independently selected, which provides for increased flexibility in configuring various performance attributes of the PCM device such as power consumption and/or memory window.

As described in greater detail above, some implementations described herein provide a semiconductor device. The semiconductor device includes one or more dielectric layers. The semiconductor device includes a PCM device in one or more dielectric layers. The PCM device includes a bottom contact structure, a first liner layer over and coupled to the bottom contact structure, a PCM layer over the first liner layer such that the first liner layer is under a bottom surface of the PCM layer, an electrode layer over the PCM layer, a top contact structure over the electrode layer, and a second liner layer adjacent to at least one sidewall of the PCM layer. The first liner layer includes a first material having a first resistivity. The second liner layer is coupled to the first liner layer and includes a second material having a second resistivity. The first resistivity and the second resistivity are each greater than a resistivity of tantalum nitride (TaN).

As described in greater detail above, some implementations described herein provide a semiconductor device. The semiconductor device includes a device layer. The semiconductor device includes a plurality of integrated circuit devices in the device layer. The semiconductor device includes an interconnect layer over the plurality of integrated circuit devices. The interconnect layer includes a plurality of dielectric layers interleaved by a plurality of etch stop layers. The interconnect layer includes a plurality of metallization structures disposed in the plurality of dielectric layers. A first thickness of a first metallization structure, of the plurality of metallization structures, at a bottom of the interconnect layer is less than a second thickness of a second metallization structure, of the plurality of metallization structures, above the first metallization structure. The semiconductor device includes a PCM device in one or more of the plurality of dielectric layers of the interconnect layer. The PCM device includes a first liner layer over and coupled to the second metallization structure. The PCM device includes a PCM layer over the first liner layer such that the first liner layer is under a bottom surface of the PCM layer. The PCM device includes an electrode layer over the PCM layer coupled to a third metallization structure of the plurality of metallization structures. The PCM device includes a second liner layer adjacent to at least one sidewall of the PCM layer. A bottom of the second liner layer is coupled to an end of the first liner layer. The first liner layer includes a first material. The second liner layer includes a second material. The first material and the second material are different materials.

As described in greater detail above, some implementations described herein provide a method. The method includes forming one or more dielectric layers of a semiconductor device. The method includes depositing material of a bottom contact structure of a PCM device such that the bottom contact structure is located in the one or more dielectric layers. The method includes depositing a layer stack over the one or more dielectric layers. The method includes forming a patterned masking layer over the layer stack. The method includes etching at least a subset of layers in the layer stack based on the patterned masking layer to define a PCM layer and an electrode layer of the PCM device above the PCM layer, where the PCM layer and the electrode layer are located above the bottom contact structure, and where a first liner layer of the PCM device is located between the PCM layer and the bottom contact structure. The method includes depositing a layer over the one or more dielectric layers, on sidewalls of the PCM layer, and above a top surface of the electrode layer. The method includes etching the layer to define a second liner layer on a sidewall of the PCM layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more dielectric layers; and
a phase change material (PCM) device, in one or more dielectric layers, comprising:
a bottom contact structure;
a first liner layer over and coupled to the bottom contact structure,
wherein the first liner layer comprises a first material having a first resistivity;
a PCM layer over the first liner layer such that the first liner layer is under a bottom surface of the PCM layer;
an electrode layer over the PCM layer;
a top contact structure over the electrode layer; and
a second liner layer adjacent to at least one sidewall of the PCM layer,
wherein the second liner layer is coupled to the first liner layer,
wherein the second liner layer comprises a second material having a second resistivity, and
wherein the first resistivity and the second resistivity are each greater than a resistivity of tantalum nitride (TaN).

2. The semiconductor device of claim 1, wherein the first resistivity and the second resistivity are each at least approximately 100 times greater than a third resistivity of a PCM of the PCM layer.

3. The semiconductor device of claim 1, wherein the second liner layer comprises:
a first vertical segment laterally adjacent to a first sidewall of the PCM layer; and
a second vertical segment laterally adjacent to a second sidewall of the PCM layer opposing the first sidewall.

4. The semiconductor device of claim 1, wherein the first liner layer and the second liner layer are elongated in approximately perpendicular directions.

5. The semiconductor device of claim 4, wherein the first liner layer is elongated in an approximately vertical direction; and
wherein the second liner layer is elongated in an approximately horizontal direction.

6. The semiconductor device of claim 1, wherein the first resistivity and the second resistivity are each included in a range of approximately 0.01 ohm-meters to approximately 0.1 ohm-meters.

7. The semiconductor device of claim 1, wherein the first resistivity and the second resistivity are different resistivities.

8. A semiconductor device, comprising:
a device layer;
a plurality of integrated circuit devices in the device layer;
an interconnect layer, over the plurality of integrated circuit devices, comprising:
a plurality of dielectric layers interleaved by a plurality of etch stop layers; and
a plurality of metallization structures disposed in the plurality of dielectric layers,
wherein a first thickness of a first metallization structure, of the plurality of metallization structures, at a bottom of the interconnect layer is less than a second thickness of a second metallization structure, of the plurality of metallization structures, above the first metallization structure; and
a phase change material (PCM) device, in one or more of the plurality of dielectric layers of the interconnect layer, comprising:
a first liner layer over and coupled to the second metallization structure,
wherein the first liner layer comprises a first material;
a PCM layer over the first liner layer such that the first liner layer is under a bottom surface of the PCM layer;
an electrode layer over the PCM layer coupled to a third metallization structure of the plurality of metallization structures; and
a second liner layer adjacent to at least one sidewall of the PCM layer,
wherein a bottom of the second liner layer is coupled to an end of the first liner layer,
wherein the second liner layer comprises a second material, and
wherein the first material and the second material are different materials.

9. The semiconductor device of claim 8, wherein a bottom surface of the second liner layer is on top of a top surface of the first liner layer.

10. The semiconductor device of claim 8, wherein a bottom surface of the second liner layer and a bottom surface of the first liner layer are approximately co-planar.

11. The semiconductor device of claim 10, wherein a sidewall of the second liner layer is in contact with an end surface of the first liner layer.

12. The semiconductor device of claim 8, wherein the first material comprises a carbon-containing material; and
wherein the second material comprises a nitride material.

13. The semiconductor device of claim 8, wherein the first material comprises carbon-doped tantalum nitride (TaN:C); and
wherein the second material comprises aluminum nitride (AlN).

14. The semiconductor device of claim 8, wherein a first resistivity of the first material is less than a second resistivity of the second material.

15. A method, comprising:
forming one or more dielectric layers of a semiconductor device;
depositing material of a bottom contact structure of a phase change material (PCM) device such that the bottom contact structure is located in the one or more dielectric layers;
depositing a layer stack over the one or more dielectric layers;
forming a patterned masking layer over the layer stack;
etching at least a subset of layers in the layer stack based on the patterned masking layer to define a PCM layer and an electrode layer of the PCM device above the PCM layer,
wherein the PCM layer and the electrode layer are located above the bottom contact structure, and
wherein a first liner layer of the PCM device is located between the PCM layer and the bottom contact structure;
depositing a layer over the one or more dielectric layers, on sidewalls of the PCM layer, and above a top surface of the electrode layer; and
etching the layer to define a second liner layer on a sidewall of the PCM layer.

16. The method of claim 15, wherein etching the at least the subset of the layer stack comprises:
etching the layer stack to define the first liner layer from the layer stack.

17. The method of claim 16, wherein depositing the layer comprises:
depositing the layer such that the layer contacts ends of the first liner layer.

18. The method of claim 15, wherein etching the layer to define the second liner layer comprises:
etching the layer and another layer of the layer stack to define the second liner layer from the layer and to define the first liner layer from the other layer of the layer stack.

19. The method of claim 15, further comprising:
forming another masking layer over the PCM device after etching the layer to define the second liner layer;
forming a recess through the other masking layer such that a first segment of the second liner layer on a first sidewall of the PCM layer is exposed in the recess; and
etching the first segment to remove the first segment from the first sidewall of the PCM layer,
wherein a second segment of the second liner layer remains on a second sidewall of the PCM layer.

20. The method of claim 18, wherein the first liner layer and the second liner layer are formed of different materials.
